(19) United States
(12) Patent Application Publication
(10) Pub. No.: US 2026/0319305 A1
(43) Pub. Date: Oct. 15, 2026

(54) Display Device

(71) Applicant: Semiconductor Energy Laboratory Co., Ltd., Kanagawa-ken (JP)

(72) Inventors: Koji KUSUNOKI, Isehara, Kanagawa (JP); Susumu KAWASHIMA, Atsugi, Kanagawa (JP); Manabu SATO, Oyama, Tochigi (JP)

(73) Assignee: Semiconductor Energy Laboratory Co., Ltd., Kanagawa-ken (JP)

(21) Appl. No.: 19/482,903

(22) PCT Filed: May 10, 2024
(86) PCT No.: PCT/IB2024/054541

§ 371 Date: Nov. 10, 2025

(30) Foreign Application Priority Data
May 17, 2023 (JP) 2023-081483

(51) Int. Cl. G02F 1/1368

(52) U.S. Cl. CPC G02F 1/1368

(57) ABSTRACT

A liquid crystal display device with a high aperture ratio is provided. A high-definition liquid crystal display device is provided. The display device includes a transistor, a liquid crystal element, and a first insulating layer. The transistor includes a semiconductor layer, a gate insulating layer, a gate electrode, and a first conductive layer. The first insulating layer includes a first side surface. The first side surface is positioned over the first conductive layer. The semiconductor layer is in contact with the top surface of the first conductive layer and the first side surface, and includes a portion positioned over the first insulating layer. The gate insulating layer includes a surface facing the first side surface with the semiconductor layer therebetween. The gate electrode includes a surface facing the first side surface with the semiconductor layer and the gate insulating layer therebetween. The liquid crystal element includes a liquid crystal, a second conductive layer, and the semiconductor layer. The second conductive layer is positioned over the first insulating layer, and includes a portion overlapping with the semiconductor layer. The semiconductor layer contains a metal oxide.

### TECHNICAL FIELD

One embodiment of the present invention relates to a semiconductor device. One embodiment of the present invention relates to a transistor. One embodiment of the present invention relates to a display device including a transistor.

Note that one embodiment of the present invention is not limited to the above technical field. Examples of the technical field of one embodiment of the present invention disclosed in this specification and the like include a semiconductor device, a display device, a light-emitting apparatus, a power storage device, a memory device, an electronic device, a lighting device, an input device, an input/output device, a driving method thereof, and a manufacturing method thereof. A semiconductor device refers to any device that can function by utilizing semiconductor characteristics.

### BACKGROUND ART

An example of a display device is a liquid crystal display device with a liquid crystal element used as a display element. For example, an active matrix liquid crystal display device in which pixel electrodes are arranged in a matrix and a switching element is connected to each of the pixel electrodes is used for various devices such as a smartphone, a tablet terminal, a monitor device, a television device, and digital signage.

It is known that liquid crystal display devices are classified into two major types: transmissive type and reflective type. A liquid crystal display device can display brighter images as the effective light-emitting area ratio (also referred to as an aperture ratio) of a pixel is higher, which also brings about a reduction in power consumption; thus, an improvement in aperture ratio is required.

An active matrix liquid crystal display device in which transistors including a metal oxide in channel formation regions are used as switching elements connected to respective pixel electrodes is known, for example. Patent Document 1 discloses a liquid crystal display device in which a transistor including metal oxide in its channel formation region is used to improve the aperture ratio.

### REFERENCE

### Patent Document

[Patent Document 1] Japanese Published Patent Application No. 2018-189938

### SUMMARY OF THE INVENTION

### Problems to be Solved by the Invention

An object of one embodiment of the present invention is to provide a liquid crystal display device with a high aperture ratio. Another object is to provide a high-definition liquid crystal display device. Another object is to provide a liquid crystal display device with low power consumption. Another object is to provide a liquid crystal display device capable of high speed operation. Another object is to provide a display device with high display quality.

An object of one embodiment of the present invention is to provide a transistor that can be miniaturized. Another object is to provide a transistor having good electrical characteristics. Another object is to provide a transistor having a small channel length. Another object is to provide a transistor that occupies a small area.

An object of one embodiment of the present invention is to provide a transistor, a display device, an electronic device, or the like that has a novel structure. Another object of one embodiment of the present invention is to provide a transistor, a display device, an electronic device, or the like that has high reliability. An object of one embodiment of the present invention is to at least alleviate at least one of problems of the conventional technique.

Note that the description of these objects does not preclude the existence of other objects. One embodiment of the present invention does not necessarily need to achieve all these objects. Other objects can be derived from the description of the specification, the drawings, the claims, and the like.

### Means for Solving the Problems

One embodiment of the present invention is a display device including a transistor, a liquid crystal element, and a first insulating layer. The transistor includes a semiconductor layer, a gate insulating layer, a gate electrode, and a first conductive layer. The first insulating layer includes a first side surface. The first side surface is positioned over the first conductive layer. The semiconductor layer is in contact with a top surface of the first conductive layer and the first side surface, and includes a portion positioned over the first insulating layer. The gate insulating layer includes a surface facing the first side surface with the semiconductor layer therebetween. The gate electrode includes a surface facing the first side surface with the semiconductor layer and the gate insulating layer therebetween. The liquid crystal element includes a liquid crystal, a second conductive layer, and the semiconductor layer. The second conductive layer is positioned over the first insulating layer, and includes a portion overlapping with the semiconductor layer. The semiconductor layer contains a metal oxide.

Another embodiment of the present invention is a display device including a transistor, a liquid crystal element, and a first insulating layer. The transistor includes a semiconductor layer, a gate insulating layer, a gate electrode, and a first conductive layer. The first insulating layer is provided with an opening reaching the first conductive layer, and includes a first side surface positioned in the opening. The semiconductor layer is in contact with a top surface of the first conductive layer and the first side surface, and includes a portion positioned over the first insulating layer. The gate insulating layer includes a surface facing the first side surface with the semiconductor layer therebetween. The gate electrode includes a surface facing the first side surface with the semiconductor layer and the gate insulating layer therebetween. The liquid crystal element includes a liquid crystal, a second conductive layer, and the semiconductor layer. The second conductive layer is positioned over the first insulating layer and includes a portion overlapping with the semiconductor layer. The semiconductor layer contains a metal oxide.

In any of the above, the first insulating layer preferably includes a first insulating film and a second insulating film over the first insulating film. The second insulating film preferably contains more hydrogen than the first insulating film does. The semiconductor layer is preferably provided in contact with the second insulating film. In addition, it is preferable that the first insulating film include an oxide and the second insulating film include a nitride.

In any of the above, the second conductive layer is preferably positioned over the semiconductor layer and contains a metal oxide. The gate insulating layer preferably includes a portion positioned between the second conductive layer and the semiconductor layer.

In the above, the second conductive layer is preferably provided over the gate insulating layer.

Alternatively, in the above, a second insulating layer is preferably provided over the gate insulating layer. The second conductive layer preferably includes a portion overlapping with the semiconductor layer with the gate insulating layer and the second insulating layer therebetween. The second conductive layer preferably includes a portion overlapping with the gate electrode with the second insulating layer therebetween.

In any of the above, a third insulating layer is preferably provided over the second conductive layer. In that case, the semiconductor layer preferably includes a portion overlapping with the second conductive layer with the third insulating layer therebetween.

In the above, the first insulating layer preferably includes a first insulating film and a second insulating film over the first insulating film. The second conductive layer is preferably positioned over the second insulating film. It is preferable that the third insulating layer contain more hydrogen than the first insulating film does and the semiconductor layer be provided in contact with the third insulating layer.

### Effect of the Invention

According to one embodiment of the present invention, a liquid crystal display device with a high aperture ratio can be provided. A high-definition liquid crystal display device can be provided. A liquid crystal display device with low power consumption can be provided. A liquid crystal display device capable of high speed operation can be provided. A display device with high display quality can be provided.

According to one embodiment of the present invention, a transistor that can be miniaturized can be provided. A transistor having good electrical characteristics can be provided. A transistor having a small channel length can be provided. A transistor that occupies a small area can be provided.

According to one embodiment of the present invention, a transistor, a display device, an electronic device, or the like that has a novel structure can be provided. According to one embodiment of the present invention, a transistor, a display device, an electronic device, or the like that has high reliability can be provided. According to one embodiment of the present invention, at least one of problems of the conventional technique can be at least alleviated.

Note that the description of these effects does not preclude the existence of other effects. One embodiment of the present invention does not necessarily need to have all these effects. Note that effects other than these can be derived from the description of the specification, the drawings, the claims, and the like.

### BRIEF DESCRIPTION OF THE DRAWINGS

FIG. 1A and FIG. 1B are each a structure example of a display device.

FIG. 2A and FIG. 2B are each a structure example of a display device.

FIG. 3A and FIG. 3B are each a structure example of a display device.

FIG. 4A and FIG. 4B are each a structure example of a display device.

FIG. 5A and FIG. 5B are each a structure example of a display device.

FIG. 6A and FIG. 6B are each a structure example of a display device.

FIG. 7A and FIG. 7B are each a structure example of a display device.

FIG. 8A and FIG. 8B are each a structure example of a display device.

FIG. 9A and FIG. 9B are each a structure example of a display device.

FIG. 10A and FIG. 10B are each a structure example of a display device.

FIG. 11A1 to FIG. 11B2 are each a structure example of a display device.

FIG. 12A to FIG. 12E are each a structure example of a display device.

FIG. 13 is a structure example of a display device.

FIG. 14 is a structure example of a display device.

FIG. 15 is a structure example of a display device.

FIG. 16 is a structure example of a display device.

FIG. 17 is a structure example of a display device.

FIG. 18A is a block diagram of a display device. FIG. 18B and FIG. 18C are circuit diagrams of the display device.

FIG. 19A, FIG. 19C, and FIG. 19D are circuit diagrams of a display device. FIG. 19B is a timing chart.

FIG. 20 is a block diagram of a touch panel module.

FIG. 21A to FIG. 21C are each a structure example of a touch panel module.

FIG. 22A to FIG. 22F are each a structure example of an electronic device.

### MODE FOR CARRYING OUT THE INVENTION

Embodiments will be described below with reference to the drawings. Note that the embodiments can be implemented in many different modes, and it will be readily understood by those skilled in the art that modes and details thereof can be changed in various ways without departing from the spirit and scope thereof. Therefore, the present invention should not be construed as being limited to the description of embodiments below.

Note that in structures of the invention described below, the same portions or portions having similar functions are denoted by the same reference numerals in different drawings, and the description thereof is not repeated. The same hatching pattern is used for portions having similar functions, and the portions are not especially denoted by reference numerals in some cases.

Note that in each drawing described in this specification, the size, the layer thickness, or the region of each component is exaggerated for clarity in some cases. Therefore, the size, the layer thickness, or the region is not limited to the illustrated scale.

Note that in this specification and the like, ordinal numbers such as “first” and “second” are used in order to avoid confusion among components and do not limit the number.

In this specification and the like, the term “electrically connected” includes the case where components are connected to each other through an object having any electric action. There is no particular limitation on an “object having any electric function” as long as electric signals can be transmitted and received between components that are connected through the object. Examples of the “object having any electric function” include a switching element such as a transistor, a resistor, a coil, and other elements with a variety of functions as well as an electrode or a wiring.

In this specification and the like, the expression “having substantially the same top-view shapes” means that the outlines of stacked layers at least partly overlap with each other. For example, the case of processing an upper layer and a lower layer with the use of the same mask pattern or mask patterns that are partly the same is included. The expression “having substantially the same top-view shapes” also sometimes includes the case where the outlines do not completely overlap with each other; for instance, the edge of the upper layer may be positioned on the inner side or the outer side of the edge of the lower layer.

Note that in this specification and the like, the top-view shape of a component means the shape of the outline of the component in a plan view. A plan view means a view to observe the component from a normal direction of a surface where the component is formed or from a normal direction of a surface of a support (e.g., a substrate) where the component is formed.

Note that the expressions indicating directions such as “over” and “under” are basically used to correspond to the directions of drawings. However, in some cases, the direction indicating “over” or “under” in the specification does not correspond to the direction in the drawings for the purpose of description simplicity or the like. For example, when a stacking order (or a formation order) of a stacked body or the like is described, even in the case where a surface on which the stacked body is provided (e.g., a formation surface, a support surface, an adhesion surface, or a planar surface) is positioned above the stacked body in the drawings, the following expressions are used in some cases: the formation surface is positioned below the stacked body or the stacked body is positioned above the formation surface.

In this specification and the like, the term “film” and the term “layer” can be interchanged with each other. For example, in some cases, the term “insulating layer” can be interchanged with the term “insulating film”.

In this specification and the like, a display panel that is one embodiment of a display device has a function of displaying (outputting) an image or the like on (to) a display surface. Therefore, the display panel is one embodiment of an output device.

In this specification and the like, a structure where a connector such as an FPC (Flexible Printed Circuit) or a TCP (Tape Carrier Package) is attached to a substrate of a display panel, or a structure where an IC is mounted on the substrate by a COG (Chip On Glass) method or the like is referred to as a display panel module or a display module, or simply as a display panel or the like in some cases.

Note that in this specification and the like, a touch panel that is one embodiment of a display device has a function of displaying an image or the like on a display surface and a function of a touch sensor capable of detecting the contact, press, approach, or the like of a sensing target such as a finger or a stylus with or to the display surface. Thus, the touch panel is one embodiment of an input/output device.

A touch panel can also be referred to as, for example, a display panel (or a display device) with a touch sensor, or a display panel (or a display device) having a touch sensor function. A touch panel can include a display panel and a touch sensor panel. Alternatively, a touch panel can have a function of a touch sensor in the display panel or on the surface of the display panel.

In this specification and the like, a structure in which a connector or an IC is mounted on a substrate of a touch panel is referred to as a touch panel module or a display module, or simply as a touch panel or the like in some cases.

### Embodiment 1

In this embodiment, a transistor of one embodiment of the present invention and a display device including the transistor will be described.

The transistor of one embodiment of the present invention includes a semiconductor layer, a gate insulating layer, a gate electrode, and a first electrode. The first electrode functions as one of a source electrode and a drain electrode. A portion of the semiconductor layer functions as the other of the source electrode and the drain electrode.

The portion of the semiconductor layer that functions as the other of the source electrode and the drain electrode (the portion is also referred to as a second electrode) is provided above the first electrode. Between the first electrode and the second electrode, an insulating layer functioning as a spacer is provided. An opening reaching the first electrode is provided in the spacer, and the semiconductor layer is provided in contact with the first electrode and a side wall (also referred to as a side surface) of the insulating layer in the opening. The gate insulating layer and the gate electrode are provided to cover the semiconductor layer.

In the transistor having the above structure, the source electrode and the drain electrode are positioned at different heights, so that the current flowing through the semiconductor layer flows in the height direction. In other words, the channel length direction can be regarded as having a component of the height direction (the vertical direction); accordingly, the transistor of one embodiment of the present invention can also be referred to as a VFET (Vertical Field Effect Transistor), a vertical transistor, a vertical-channel transistor, and the like.

In the above transistor, the source electrode, the semiconductor layer, and the drain electrode can be provided to overlap with each other. Thus, the area occupied by the transistor can be significantly smaller than the area occupied by a so-called planar transistor (also referred to as a lateral transistor, an LFET (Lateral FET), or the like) in which a semiconductor layer is positioned on a flat plane.

Moreover, since the channel length of the transistor can be precisely controlled by the thickness of the insulating layer, a variation in the channel length can be made extremely reduced as compared with that of a planar transistor. Furthermore, by reducing the thickness of the insulating layer, a transistor with an extremely short channel length can be manufactured. For example, a transistor with a channel length of less than or equal to 2 μm, less than or equal to 1 μm, less than or equal to 500 nm, less than or equal to 300 nm, less than or equal to 200 nm, less than or equal to 100 nm, less than or equal to 50 nm, less than or equal to 30 nm, or less than or equal to 20 nm and greater than or equal to 5 nm, greater than or equal to 7 nm, or greater than or equal to 10 nm can be manufactured. Thus, it is possible to obtain a transistor with an extremely short channel length that could not be obtained with the use of a conventional lithography tool for mass production of flat panel displays (the minimum line width: approximately 2 μm or approximately 1.5 μm, for example). Moreover, it is also possible to obtain a transistor with a channel length less than 10 nm without using an extremely expensive lithography tool used in the latest LSI technology.

For the semiconductor layer, a film of metal oxide having semiconductor characteristics (also referred to as an oxide semiconductor) is particularly preferably used so that both high performance and high productivity can be achieved. In particular, an oxide semiconductor film having crystallinity is further preferably used so that high reliability can be given.

A liquid crystal display device including the above-described vertical transistor can have a significantly higher aperture ratio than a liquid crystal display device including a conventional lateral transistor. This can achieve a display device with low power consumption, a display device with improved maximum luminance, a display device with good viewing angle characteristics, a display device with high reliability, and the like.

Furthermore, a structure in which a portion of the semiconductor layer also serves as the second electrode can simplify the manufacturing process, as compared with the case where the second electrode is separately provided. In addition, a contact portion between the semiconductor layer and the second electrode, which is necessary in the case where the second electrode is separately provided, can be omitted; thus, the area occupied by the transistor can be further reduced.

When an oxide semiconductor having a light-transmitting property is used for the semiconductor layer of the transistor, a structure in which the second electrode also serves as a pixel electrode of the liquid crystal element can be obtained. This can achieve a high-definition display device. It is also possible to increase the aperture ratio (effective display area ratio) of a pixel, since the area occupied by a transistor in the pixel can be reduced.

In the case where a lateral transistor is used, a contact hole for connecting the source electrode or the drain electrode of the transistor to the pixel electrode needs to be provided. Furthermore, depending on the transistor structure, a contact hole is also used for connecting the semiconductor layer to the source electrode or the drain electrode. These contact holes and regions in the vicinity thereof cannot contribute to display because liquid crystal orientation in these regions is disordered by unevenness due to the contact holes, which is one of factors that inhibit an increase in the aperture ratio of the pixel.

Meanwhile, in one embodiment of the present invention, the semiconductor layer of the transistor also functions as the pixel electrode; thus, an interlayer insulating film and a contact hole, which are necessary in the case where a lateral transistor is used, are unnecessary and the aperture ratio of the pixel can be increased. Furthermore, as described above, the contact portion between the semiconductor layer and the second electrode of the transistor is not necessary, so that the aperture ratio can be further increased.

Any of elements with various structures can be used as the liquid crystal elements. Typically, a transmissive liquid crystal display device having a liquid crystal element employing a VA (Vertical Alignment) mode, an FFS (Fringe Field Switching) mode, an IPS (In-Plane-Switching) mode, or the like can be used. Not only a transmissive liquid crystal display device, but also a reflective or semi-transmissive liquid crystal display device can be used.

A more specific example will be described below with reference to drawings.

### Structure Example

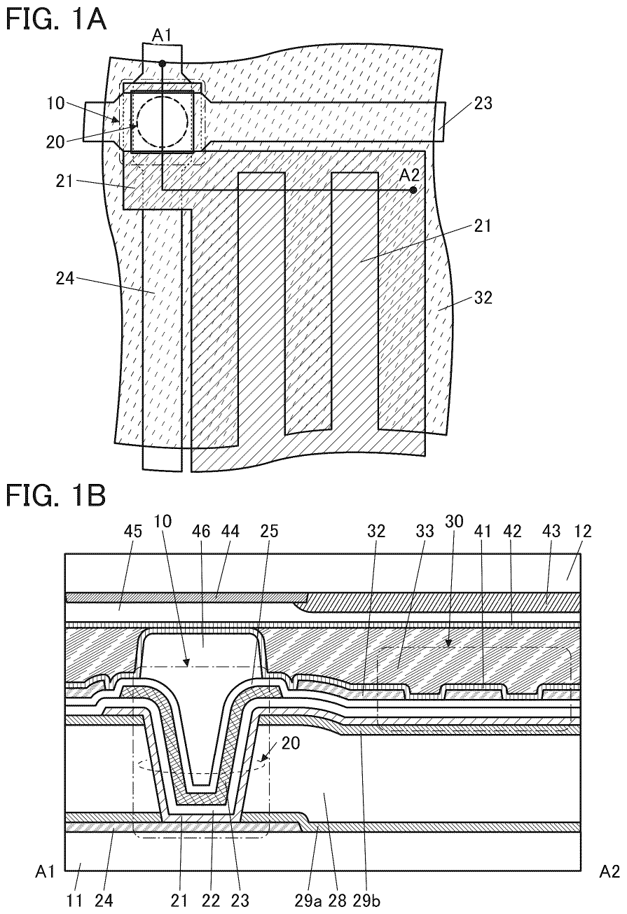

FIG. 1A is a schematic top view of a portion of a pixel of a display device. FIG. 1B is a schematic cross-sectional view taken along dashed-dotted line A1-A2 in FIG. 1A. Note that some components (e.g., an insulating layer) are not illustrated in the schematic top view for clarity. In the schematic top view, some films are cut so that a stacked structure can be seen clearly.

The display device of one embodiment of the present invention is a liquid crystal display device that includes a transistor 10 and a liquid crystal element 30 between a substrate 11 and a substrate 12.

As illustrated in FIG. 1A, the transistor 10 is provided at an intersection portion between a conductive layer 23 and a conductive layer 24. The conductive layer 23 functions as a scan line, and a portion of the conductive layer 23 functions as a gate electrode of the transistor 10. The conductive layer 24 functions as a signal line, and a portion of the conductive layer 24 functions as one of a source electrode and a drain electrode of the transistor 10.

The transistor 10 is provided over the substrate 11 and includes a semiconductor layer 21, an insulating layer 22, the conductive layer 23, and the conductive layer 24. The insulating layer 22 functions as a gate insulating layer.

The liquid crystal element 30 includes the semiconductor layer 21 functioning as a pixel electrode, a conductive layer 32 functioning as a common electrode, and a liquid crystal 33. The conductive layer 32 is provided between the semiconductor layer 21 and the liquid crystal 33. The conductive layer 32 is provided with slits overlapping with the semiconductor layer 21 as illustrated in FIG. 1A. The liquid crystal element 30 illustrated in FIG. 1A is a liquid crystal element employing the FFS mode.

A portion of the semiconductor layer 21 functions as a channel formation region, and another portion functions as the other of the source electrode and the drain electrode. A portion of the portion of the semiconductor layer 21 that functions as the other of the source electrode and the drain electrode functions as a pixel electrode.

As illustrated in FIG. 1B, the conductive layer 24 is provided over the substrate 11 and an insulating layer 29a, an insulating layer 28, and an insulating layer 29b are provided in this order to cover the conductive layer 24. An opening 20 reaching the conductive layer 24 is provided in the insulating layer 29b, the insulating layer 28, and the insulating layer 29a. It can be said that, for example, side walls (side surfaces) of the insulating layer 29b, the insulating layer 28, and the insulating layer 29a along the opening 20 overlap with the conductive layer 24.

The semiconductor layer 21 is in contact with the top surface of the conductive layer 24 positioned at the bottom of the opening 20; a side surface of the insulating layer 29a, a side surface of the insulating layer 28, and a side surface of the insulating layer 29b along the opening 20; and a top surface of the insulating layer 29b. A portion of the semiconductor layer 21 that is in contact with the conductive layer 24 functions as one of a source region and a drain region. It can be said that a portion of the semiconductor layer 21 that is in contact with the insulating layer 29b functions as the other of the source region and the drain region. A region of the semiconductor layer 21 that is between these portions (in particular, a region in contact with the insulating layer 28) functions as a region where a channel is formed (channel formation region). It is preferable that in the semiconductor layer 21, a region in contact with the insulating layer 29a and a region in contact with the insulating layer 29b have a higher carrier concentration and a lower resistance than the channel formation region.

The insulating layer 22 functioning as the gate insulating layer is provided to cover the insulating layer 29b and the semiconductor layer 21. In addition, the conductive layer 23 functioning as the gate electrode is provided to cover the insulating layer 22.

As described above, the semiconductor layer 21 includes a portion that is in contact with the side surface of the insulating layer 28 and functions as a channel formation region. In the opening 20, the insulating layer 22 includes a portion (surface) facing the side surface of the insulating layer 28 with the semiconductor layer 21 therebetween. The conductive layer 23 includes a portion (surface) facing the side surface of the insulating layer 28 with the semiconductor layer 21 and the insulating layer 22 therebetween. An interface between the semiconductor layer 21 and the insulating layer 22 and an interface between the insulating layer 22 and the conductive layer 23 each include a portion parallel to the side surface of the insulating layer 28.

An insulating layer 25 functioning as a protective layer is provided to cover the insulating layer 22 and the conductive layer 23. Furthermore, the conductive layer 32 functioning as a common electrode and an insulating layer 46 functioning as a spacer are provided over the insulating layer 25. For the insulating layer 46, a photosensitive resin can be used. The insulating layer 46 can be formed by forming a photosensitive resin over the insulating layer 25 and then performing light exposure and development, for example. As the photosensitive resin, a negative or positive photosensitive resin can be used.

The insulating layer 46 has a function of controlling the distance between the substrate 11 and the substrate 12 to control the thickness of the liquid crystal 33. Furthermore, the insulating layer 46 is preferably provided to fill a depressed portion on the top surface of the insulating layer 25 due to the opening 20. When the insulating layer 46 is provided to overlap with the transistor 10, a decrease in the aperture ratio caused by providing the insulating layer 46 can be inhibited.

Here, the area of the transistor 10 in the plan view is smaller than that of a lateral transistor; thus, the insulating layer 46 placed in a region overlapping with the transistor 10 also has a small area. Therefore, in the case where the strength as a spacer is insufficient, it is preferable that the insulating layer 46 be provided in every subpixel. Accordingly, sufficient strength can be obtained even in the case where the insulating layer 46 has a small area.

Although a structure in which the insulating layer 46 is provided on the substrate 11 side is employed here, the insulating layer 46 may be provided on the substrate 12 side. In that case, a structure in which an alignment film 41 is provided in contact with a portion of the insulating layer 25 that overlaps with the transistor 10 can be employed. It is also possible to provide the insulating layer 46 on both the substrate 11 side and the substrate 12 side.

The conductive layer 32 functioning as a common electrode includes a portion overlapping with the semiconductor layer 21 with the insulating layer 25 and the insulating layer 22 therebetween. A portion where the conductive layer 32, the insulating layer 25, the insulating layer 22, and the semiconductor layer 21 are stacked functions as a storage capacitor of a pixel. In that case, the conductive layer 32 and the semiconductor layer 21 function as a pair of electrodes of a capacitor. The insulating layer 25 and the insulating layer 22 function as a dielectric of the capacitor.

In the conductive layer 32, a slit is provided in a portion of a region overlapping with the semiconductor layer 21, and an opening is provided in a region overlapping with the opening 20. The alignment film 41 is provided to cover the conductive layer 32, the insulating layer 46, and the insulating layer 25.

In one embodiment of the present invention, a portion of the semiconductor layer 21 of the transistor 10 serves as both the other of the source electrode and the drain electrode of the transistor 10 and the pixel electrode of the liquid crystal element 30. With such a structure, the manufacturing process can be significantly simplified and the manufacturing cost can be reduced as compared with the case where these three are formed separately. Furthermore, the number of necessary interlayer insulating films can also be reduced; accordingly, scattering of light from a backlight can be reduced, which leads to an increase in power efficiency and a reduction in power consumption.

Here, the pixel electrode of the liquid crystal element 30 needs to have a high light-transmitting property. Thus, it is preferable to use an oxide semiconductor having a light-transmitting property for the semiconductor layer 21 of the transistor 10. Thus, the semiconductor layer 21 can have three functions: a function of the semiconductor layer of the transistor 10, a function of one of the source electrode and the drain electrode, and a function of the pixel electrode. Here, in the case where silicon is used for the semiconductor layer 21, silicon has a property of absorbing part of visible light, and silicon which is supplied with a dopant and reduced in resistance absorbs visible light even more easily. For this reason, an oxide semiconductor, which has a higher light-transmitting property than silicon, is suitably used for the semiconductor layer 21.

A coloring layer 43, a light-blocking layer 44, an insulating layer 45, and an alignment film 42 are provided on a surface of the substrate 12 on the substrate 11 side. The alignment film 42 may include a portion that overlaps with the insulating layer 46 and is in contact with the alignment film 41. Note that the alignment film 41 and/or the alignment film 42 do/does not need to be provided when not needed.

A portion where the light-blocking layer 44 is provided serves as a non-light-emitting region. In one embodiment of the present invention, the light-blocking layer 44 can be provided in a region that covers the transistor 10, the conductive layer 23, and the conductive layer 24. In one embodiment of the present invention, since a contact hole for connecting a pixel electrode and a transistor is not provided, the area of the non-light-emitting region where the light-blocking layer 44 is provided can be significantly reduced as compared with the conventional case.

The coloring layer 43 can also be referred to as a color filter, and converts light of a light source such as a backlight into light exhibiting a specific color. For example, the coloring layer 43 of red, green, or blue is provided as a coloring layer in each pixel (subpixel); thus, full-color display can be performed. Note that the provision of a pixel (subpixel) corresponding to yellow, white, or the like in addition to the three colors is preferable since power consumption can be reduced. In the case where a white pixel is used, a color filter is not provided in the pixel.

A structure may be employed in which blue or violet light is used for the light source and the coloring layer 43 is formed using a color conversion material that converts the blue or violet light into light of another color (e.g., red or green). As the color conversion material, a fluorescent material, a phosphorescent material, a resin material where quantum dots are dispersed, or the like can be used. Note that in this case, the coloring layer 43 preferably has a structure in which a color conversion material and a color filter are stacked from the backlight side in order that the coloring layer 43 may absorb light passing through the color conversion material.

The insulating layer 45 functions as an overcoat that prevents diffusion of components contained in the coloring layer 43 and the like into the liquid crystal 33. The insulating layer 45 also functions as a planarization film. The insulating layer 45 can be formed using a light-transmitting organic resin.

The substrate 11 and the substrate 12 are attached to each other by an adhesive layer (not illustrated) provided outside a display portion. The distance between the substrate 11 and the substrate 12 is controlled by the insulating layer 46 functioning as a spacer.

Here, the liquid crystal element 30 employs a mode in which a pixel electrode and a common electrode are placed on the substrate 11 side and an electric field is applied to the liquid crystal 33 in a direction perpendicular to the thickness direction. Note that the arrangement of the electrodes is not limited thereto, and a method in which an electric field is applied to the liquid crystal 33 in a direction parallel to the thickness direction may be employed.

As the display device, a normally black liquid crystal display device such as a transmissive liquid crystal display device employing a vertical alignment (VA) mode, for example, may be used. As the vertical alignment mode, an MVA (Multi-Domain Vertical Alignment) mode, a PVA (Patterned Vertical Alignment) mode, an ASV (Advanced Super View) mode, and the like can be used.

As the liquid crystal element 30, a liquid crystal element employing any of a variety of modes can be used. A liquid crystal element can employ, for example, a TN (Twisted Nematic) mode, an IPS mode, an ASM (Axially Symmetric aligned Micro-cell) mode, an OCB (Optically Compensated Birefringence) mode, an FLC (Ferroelectric Liquid Crystal) mode, an AFLC (AntiFerroelectric Liquid Crystal) mode, an ECB (Electrically Controlled Birefringence) mode, a guest-host mode, or the like in addition to a VA mode and an FFS mode.

Here, the liquid crystal display device is a display device that controls transmission and non-transmission of light by utilizing polarized light and an optical modulation action of a liquid crystal. The optical modulation action of a liquid crystal is controlled by an electric field applied to the liquid crystal (including a horizontal electric field, a vertical electric field, or an oblique electric field). As the liquid crystal that can be used for the liquid crystal element, a thermotropic liquid crystal, a low-molecular liquid crystal, a high-molecular liquid crystal, a polymer dispersed liquid crystal (PDLC), a polymer network liquid crystal (PNLC), a ferroelectric liquid crystal, an anti-ferroelectric liquid crystal, or the like can be used. Such a liquid crystal material exhibits a cholesteric phase, a smectic phase, a cubic phase, a chiral nematic phase, an isotropic phase, or the like depending on conditions. As the liquid crystal material, either a positive liquid crystal or a negative liquid crystal may be used, and an appropriate liquid crystal material can be used depending on the mode or design to be used.

Although not illustrated in FIG. 1B, in the case of a transmissive liquid crystal, a polarizing plate is provided on each of an outer surface of the substrate 11 and an outer surface of the substrate 12. Furthermore, a backlight is provided on an outer side of the substrate 11. In that case, the substrate 12 side is a display surface side.

The semiconductor layer 21 preferably includes a metal oxide (an oxide semiconductor) with a light-transmitting property.

Examples of a metal oxide that can be used for the semiconductor layer 21 include an In oxide, a Ga oxide, and a Zn oxide. The metal oxide preferably contains at least In or Zn. Alternatively, the metal oxide preferably contains at least In or Ga. The metal oxide preferably contains two or three elements selected from In, an element M, and Zn. The element M is a metal element or metalloid element that has a high bonding energy with oxygen, such as a metal element or metalloid element whose bonding energy with oxygen is higher than that of In. Specific examples of the element M include Al, Ga, Sn, Y, Ti, V, Cr, Mn, Fe, Co, Ni, Zr, Mo, Hf, Ta, W, La, Ce, Nd, Mg, Ca, Sr, Ba, B, Si, Ge, and Sb. The element M contained in the metal oxide is preferably one or more kinds selected from the above elements. Specifically, the element M is preferably one or more kinds selected from Al, Ga, Y, and Sn, further preferably Ga. Hereinafter, a metal oxide containing In, M, and zinc is referred to as In-M-Zn oxide in some cases. In this specification and the like, a metal element and a metalloid element may be collectively referred to as a “metal element” and a “metal element” in this specification and the like may refer to a metalloid element.

When the metal oxide is In-M-Zn oxide, the proportion of the number of In atoms is preferably greater than or equal to that of the number of element M atoms in the In-M-Zn oxide. Examples of the atomic ratio of the metal elements of such In-M-Zn oxide include In:M:Zn=1:1:1, In:M:Zn=1:1:1.2, In:M:Zn=2:1:3, In:M:Zn=3:1:2, In:M:Zn=4:2:3, In:M:Zn=4:2:4.1, In:M:Zn=5:1:3, In:M:Zn=5:1:6, In:M:Zn=5:1:7, In:M:Zn=5:1:8, In:M:Zn=6:1:6, and In:M:Zn=5:2:5 and a composition in the vicinity of any of the above atomic ratios. Note that the composition in the vicinity includes the range of ±30 % of an intended atomic ratio. By increasing the proportion of the number of indium atoms in the metal oxide, the on-state current, field-effect mobility, or the like of the transistor can be improved.

The proportion of the number of In atoms may be less than that of the number of M atoms in the In-M-Zn oxide. Examples of the atomic ratio of the metal elements of such In-M-Zn oxide include In:M:Zn=1:3:2, In:M:Zn=1:3:3, and In:M:Zn=1:3:4 and a composition in the vicinity of any of the above atomic ratios. By increasing the proportion of the number of element M atoms in the metal oxide, generation of oxygen vacancies can be suppressed.

For the semiconductor layer 21, for example, In—Zn oxide, In—Ga oxide, In—Sn oxide, In—Ti oxide, In—Ga—Al oxide, In—Ga—Sn oxide, In—Ga—Zn oxide, In—Sn—Zn oxide, In—Al—Zn oxide, In—Ti—Zn oxide, In—Ga—Sn—Zn oxide, or In—Ga—Al—Zn oxide can be used. Alternatively, Ga—Zn oxide may be used.

Note that the metal oxide may contain, instead of or in addition to In, one or more kinds selected from metal elements belonging to a period of a higher number in the periodic table. As the overlap between orbits of metal elements is larger, the metal oxide tends to have higher carrier conductivity. Thus, a transistor containing a metal element belonging to a period of a higher number in the periodic table can have high field-effect mobility in some cases. Examples of the metal element belonging to a period of a higher number in the periodic table include metal elements belonging to Period 5 and metal elements belonging to Period 6. Specific examples of the metal element include Y, Zr, Ag, Cd, Sn, Sb, Ba, Pb, Bi, La, Ce, Pr, Nd, Pm, Sm, and Eu. Note that La, Ce, Pr, Nd, Pm, Sm, and Eu are referred to as light rare earth elements.

The metal oxide may contain one or more kinds selected from nonmetallic elements. A transistor including the metal oxide containing a nonmetallic element can have high field-effect mobility in some cases. Examples of the nonmetallic element include carbon, nitrogen, phosphorus, sulfur, selenium, fluorine, chlorine, bromine, and hydrogen.

A sputtering method or an atomic layer deposition (ALD) method can be suitably used for forming the metal oxide. Note that in the case where the metal oxide is formed by a sputtering method, the composition of the deposited metal oxide may be different from the composition of a target. In particular, the zinc content of the deposited metal oxide may be reduced to approximately 50% of that of the target.

In this specification and the like, the content of a certain metal element in a metal oxide refers to the proportion of the number of atoms of the metal element to the total number of metal element atoms contained in the metal oxide. In the case where a metal oxide contains a metal element X, a metal element Y, and a metal element Z and the atomic numbers of the metal element X, the metal element Y, and the metal element Z contained in the metal oxide are respectively represented by A_{X}, A_{Y}, and A_{Z}, the content of the metal element X can be represented by A_{X}/(A_{X}+A_{Y}+A_{Z}). Moreover, in the case where the atomic ratio of the metal element X to the metal element Y and the metal element Z contained in the metal oxide is represented by B_{X}:B_{Y}:B_{Z}, the content of the metal element X can be represented by B_{X}/(B_{X}+B_{Y}+B_{Z}).

In the case of using a metal oxide containing In, for example, an increase in the In content enables a transistor to have a high on-state current.

When the semiconductor layer 21 includes a metal oxide not containing Ga or having a low Ga content, a transistor can have high reliability against positive bias application. That is, the transistor can show a small amount of change in the threshold voltage in the PBTS (Positive Bias Temperature Stress) test. In the case of using a metal oxide containing Ga, the Ga content is preferably lower than the In content. Accordingly, the transistor can have high mobility and high reliability.

Meanwhile, a transistor having a high Ga content can have high reliability against light. That is, the transistor can show a small amount of change in the threshold voltage of the transistor in the NBTIS (Negative Bias Temperature Illumination Stress) test. Specifically, a metal oxide in which the proportion of the number of Ga atoms is greater than or equal to that of the number of In atoms has a wider band gap and can reduce the amount of change in the threshold voltage of the transistor in the NBTIS test.

Furthermore, a metal oxide having a high zinc content has high crystallinity, whereby diffusion of impurities in the metal oxide can be inhibited. Consequently, a change in electrical characteristics of the transistor is suppressed and the transistor can have high reliability.

The semiconductor layer 21 may have a stacked-layer structure including two or more metal oxide layers. The two or more metal oxide layers included in the semiconductor layer 21 may have the same composition or substantially the same compositions. Employing a stacked-layer structure of metal oxide layers having the same composition can reduce the manufacturing cost because the metal oxide layers can be formed using the same sputtering target. Note that a stacked-layer structure including two or more oxide semiconductor layers having different compositions may be employed.

It is preferable to use a metal oxide layer having crystallinity as the semiconductor layer 21. For example, a metal oxide layer having a CAAC (c-axis aligned crystal) structure, a polycrystalline (Poly-crystal) structure, a nano-crystal (nc) structure, or the like can be used. By using a metal oxide layer having crystallinity as the semiconductor layer 21, the density of defect states in the semiconductor layer 21 can be reduced, which enables the semiconductor device to have high reliability.

The CAAC structure is a crystal structure in which a plurality of microcrystals (typically, a plurality of IGZO microcrystals) have c-axis alignment, and the plurality of microcrystals are connected on the a-b plane without alignment. The CAAC structure has a smaller amount of crystal grain boundary, grain, or the like in the a-b plane than a polycrystalline structure, and thus can achieve a highly reliable semiconductor device.

As the crystallinity of the metal oxide layer used as the semiconductor layer 21 becomes higher, the density of defect states in the semiconductor layer 21 can be reduced. In contrast, the use of a metal oxide layer having low crystallinity enables a transistor to flow a large amount of current.

A transistor including an oxide semiconductor (hereinafter referred to as an OS transistor) has much higher field-effect mobility than a transistor including amorphous silicon. In addition, the OS transistor has an extremely low leakage current between a source and a drain in an off state (the leakage current is hereinafter also referred to as an off-state current), and charge accumulated in a capacitor that is connected in series to the transistor can be retained for a long period. Furthermore, the power consumption of the semiconductor device can be reduced with the OS transistor.

Since an OS transistor has a higher withstand voltage between the source and the drain than a transistor including silicon (hereinafter referred to as a Si transistor), a high voltage can be applied between the source and the drain of the OS transistor. Furthermore, when transistors operate in a saturation region, a change in a source-drain current relative to a change in a gate-source voltage can be smaller in an OS transistor than in a Si transistor.

A change in electrical characteristics of an OS transistor due to irradiation with radiation is small, i.e., an OS transistor has high resistance to radiation; thus, an OS transistor can be suitably used even in an environment where radiation can enter. It can also be said that an OS transistor has high reliability against radiation. For example, an OS transistor can be suitably used for a pixel circuit of an X-ray flat panel detector. Moreover, an OS transistor can be suitably used for a semiconductor device used in space. Examples of radiation include electromagnetic radiation (e.g., X-rays and gamma rays) and particle radiation (e.g., alpha rays, beta rays, a proton beam, and a neutron beam).

Note that a semiconductor material that can be used for the semiconductor layer 21 is not limited to an oxide semiconductor. For example, a single-element semiconductor or a compound semiconductor can be used. Examples of the single-element semiconductor include silicon (such as single crystal silicon, polycrystalline silicon, microcrystalline silicon, and amorphous silicon) and germanium. Examples of the compound semiconductor include gallium arsenide and silicon germanium. Examples of the compound semiconductor include an organic semiconductor, a nitride semiconductor, and an oxide semiconductor. These semiconductor materials may contain impurities as dopants.

Alternatively, the semiconductor layer 21 may include a layered material functioning as a semiconductor. The layered material generally refers to a group of materials having a layered crystal structure. In the layered crystal structure, layers formed by covalent bonding or ionic bonding are stacked with bonding such as the Van der Waals binding, which is weaker than covalent bonding or ionic bonding. The layered material has high electrical conductivity in a unit layer, that is, high two-dimensional electrical conductivity. When a material that functions as a semiconductor and has high two-dimensional electrical conductivity is used for a channel formation region, the transistor can have a high on-state current.

Examples of the layered material include graphene, silicene, and chalcogenide. Chalcogenide is a compound containing chalcogen (an element belonging to Group 16). Examples of chalcogenide include transition metal chalcogenide and chalcogenide of Group 13 elements. Specific examples of the transition metal chalcogenide which can be used for a semiconductor layer of a transistor include molybdenum sulfide (typically MoS₂), molybdenum selenide (typically MoSe₂), molybdenum telluride (typically MoTe₂), tungsten sulfide (typically WS₂), tungsten selenide (typically WSe₂), tungsten telluride (typically WTe₂), hafnium sulfide (typically HfS₂), hafnium selenide (typically HfSe₂), zirconium sulfide (typically ZrS₂), and zirconium selenide (typically ZrSe₂).

There is no particular limitation on the crystallinity of a semiconductor material used for the semiconductor layer 21, and any of an amorphous semiconductor, a single crystal semiconductor, and a semiconductor having other crystallinity than single crystal (a polycrystalline semiconductor, a microcrystalline semiconductor, or a semiconductor partly including crystal regions) may be used. It is preferable to use a semiconductor having crystallinity, in which case deterioration of the transistor characteristics can be suppressed.

The top surface of the conductive layer 24 is in contact with the semiconductor layer 21. Here, when the semiconductor layer 21 is formed using an oxide semiconductor and the conductive layer 24 is formed using, for example, a metal that is likely to be oxidized such as aluminum, an insulating oxide (e.g., aluminum oxide) is formed between the conductive layer 24 and the semiconductor layer 21, which might inhibit continuity between the two. Therefore, the conductive layer 24 is preferably formed using a conductive material that is less likely to be oxidized, a conductive material that maintains low electric resistance even when oxidized, or an oxide conductive material.

A light-transmitting oxide conductive material can be used for the conductive layer 24. For example, a conductive oxide such as indium oxide, zinc oxide, In—Sn oxide, In—Zn oxide, In—W oxide, In—W—Zn oxide, In—Ti oxide, In—Ti—Sn oxide, In—Sn oxide containing silicon, or zinc oxide to which gallium is added can be used. A conductive oxide containing indium is particularly preferable because of its high conductivity.

Since the conductive layer 24 does not necessarily have a light-transmitting property, a conductive material that absorbs or reflects part of visible light may be used for the conductive layer 24. For example, tantalum nitride, titanium nitride, a nitride containing titanium and aluminum, a nitride containing tantalum and aluminum, ruthenium oxide, ruthenium nitride, an oxide containing strontium and ruthenium, or an oxide containing lanthanum and nickel can be used. Alternatively, titanium, ruthenium, tungsten, or the like can be used. These materials are preferable because they are conductive materials that are less likely to be oxidized or materials that maintain the conductivity even when being oxidized.

The insulating layer 22 functions as a gate insulating layer. In the case where the semiconductor layer 21 is formed using an oxide semiconductor, an oxide insulating film is preferably used for at least portions of the insulating layer 22 that are in contact with the semiconductor layer 21. For example, one or more of silicon oxide, silicon oxynitride, aluminum oxide, aluminum oxynitride, hafnium oxide, hafnium oxynitride, gallium oxide, gallium oxynitride, yttrium oxide, yttrium oxynitride, and Ga—Zn oxide can be used. In addition, as the insulating layer 22, a nitride insulating film of silicon nitride, silicon nitride oxide, aluminum nitride, or aluminum nitride oxide can also be used. The insulating layer 22 may have a stacked-layer structure, e.g., a stacked-layer structure including at least one oxide insulating film and at least one nitride insulating film.

Note that in this specification and the like, oxynitride refers to a material that contains more oxygen than nitrogen. Nitride oxide refers to a material that contains more nitrogen than oxygen.

The conductive layer 23 functions as a gate electrode and can be formed using a variety of conductive materials. The conductive layer 23 can be formed using one or more of chromium, copper, aluminum, gold, silver, zinc, molybdenum, tantalum, titanium, tungsten, manganese, nickel, iron, cobalt, molybdenum, and niobium or an alloy including one or more of these metal elements as its component, for example. For the conductive layer 23, the nitride and the oxide that can be used for the conductive layer 24 may be used.

The insulating layer 28 includes portions in contact with the semiconductor layer 21. In the case where the semiconductor layer 21 is formed using an oxide semiconductor, an oxide is preferably used for at least the portions of the insulating layer 28 that are in contact with the semiconductor layer 21 in order to improve the properties of the interface between the insulating layer 28 and the semiconductor layer 21. For example, silicon oxide or silicon oxynitride can be suitably used.

As the insulating layer 28, it is further preferable to use a film from which oxygen is released by heating. Accordingly, oxygen can be supplied to the semiconductor layer 21 owing to heat applied during the manufacturing process of the transistor 10, the amount of oxygen vacancy in the semiconductor layer 21 can be reduced, and reliability can be improved. Examples of a method for supplying oxygen to the insulating layer 28 include heat treatment in an oxygen atmosphere and plasma treatment in an oxygen atmosphere. Alternatively, an oxide film may be deposited over a top surface of the insulating layer 28 by a sputtering method in an oxygen atmosphere to supply oxygen. After that, the oxide film may be removed.

The insulating layer 28 is preferably formed by a deposition method such as a sputtering method or a plasma CVD method. In particular, the use of a sputtering method enables the film to contain an extremely small amount of hydrogen, since a hydrogen-containing gas does not need to be used as the deposition gas. Therefore, supply of hydrogen to the semiconductor layer 21 is inhibited and the electrical characteristics of the transistor 10 can be stabilized.

As the insulating layer 29a and the insulating layer 29b, films in which oxygen is less likely to be diffused are preferably used. Accordingly, it is possible to prevent oxygen contained in the insulating layer 28 from being diffused toward the substrate 11 side and the insulating layer 22 side through the insulating layer 29a and the insulating layer 29b, respectively, due to heating. In other words, when the insulating layer 29a and the insulating layer 29b in which oxygen is less likely to be diffused are respectively provided above and below the insulating layer 28 so that the insulating layer 28 is sandwiched therebetween, oxygen can be enclosed in the insulating layer 28. Accordingly, oxygen can be effectively supplied to the semiconductor layer 21.

For the insulating layer 29a and the insulating layer 29b, for example, one or more of silicon nitride, silicon nitride oxide, silicon oxynitride, aluminum oxide, aluminum oxynitride, aluminum nitride, hafnium oxide, and hafnium aluminate can be used. Silicon nitride and silicon nitride oxide are particularly suitable for the insulating layer 29a and the insulating layer 29b because they release fewer impurities (e.g., water and hydrogen) and are less likely to transmit oxygen and hydrogen.

Since the insulating layer 29b is less likely to allow oxygen to diffuse, a portion of the semiconductor layer 21 that is in contact with the top surface of the insulating layer 29b is not supplied with oxygen and thus can have a large number of oxygen vacancies. Thus, in this portion, hydrogen in the semiconductor layer 21 is bonded to the oxygen vacancies to generate carriers, which can turn this portion into a low-resistance state.

Furthermore, the insulating layer 29b may have a stacked-layer structure including an insulating film through which oxygen and hydrogen from the insulating layer 28 side are less likely to pass and an insulating film from which hydrogen is released by heating. In other words, a film from which hydrogen is released by heating is provided on the side of the insulating layer 29b that is in contact with the semiconductor layer 21. In this way, the resistance of the portion of the semiconductor layer 21 that is in contact with the insulating layer 29b can be effectively reduced. Silicon nitride, silicon nitride oxide, silicon oxynitride, silicon oxide, or the like deposited to contain hydrogen can be used, for example. At this time, when the deposition is performed at a low temperature (e.g., higher than or equal to 100 °C and lower than or equal to 400 °C, preferably higher than or equal to 100 °C and lower than or equal to 300 °C) by a deposition method using a hydrogen-containing gas (a hydrogen gas or a hydrogen compound gas) as a deposition gas, such as a plasma CVD method, a film from which a large amount of hydrogen is released can be formed. Accordingly, in the manufacturing process of the transistor 10, hydrogen is supplied from the insulating layer 29b to the semiconductor layer 21 by heat treatment performed after the formation of the semiconductor layer 21 or heat applied during the process, so that the carrier concentration in the semiconductor layer 21 can be increased and the resistance can be reduced.

Here, as illustrated in FIG. 1B, the conductive layer 23 and the semiconductor layer 21 overlap with each other with the insulating layer 22 therebetween, and the conductive layer 24 and the semiconductor layer 21 overlap with the insulating layer 29a, the insulating layer 28, and the insulating layer 29b. At this time, when the thickness of the insulating layer 22 is smaller than the thicknesses of the three layers, i.e., the insulating layer 29a, the insulating layer 28, and the insulating layer 29b, the driving voltage of the transistor 10 can be lowered. Meanwhile, the smaller the thickness of the insulating layer 22 is, the larger the parasitic capacitance between the semiconductor layer 21 and the conductive layer 23 is. Meanwhile, since the insulating layer 29a, the insulating layer 28, and the insulating layer 29b can be formed to be thicker than the insulating layer 22, the parasitic capacitance between the semiconductor layer 21 and the conductive layer 24 can be reduced. Therefore, as illustrated in FIG. 1A, it is preferable that the semiconductor layer 21 be placed such that the area overlapping with the conductive layer 23 is smaller than the area overlapping with the conductive layer 24. In this manner, a display device capable of performing display at a high driving frequency even with high resolution can be obtained.

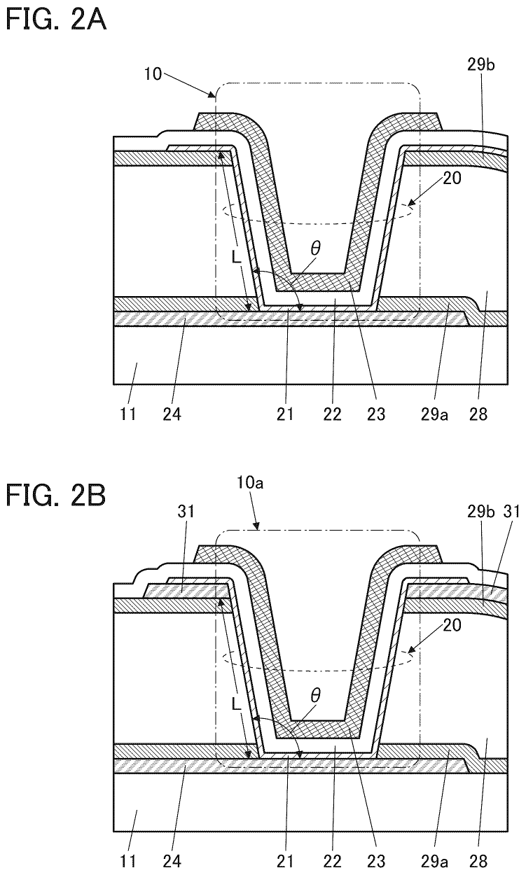

FIG. 2A is an enlarged view of a cross section of the transistor 10.

In this specification and the like, the channel length L of the transistor 10 refers to the shortest distance between a portion of the semiconductor layer 21 in contact with the conductive layer 24 and a portion of the semiconductor layer 21 in contact with the top surface of the insulating layer 29b as illustrated in FIG. 2A. As the slopes of the side surfaces of the insulating layer 29a, the insulating layer 28, and the insulating layer 29b in the opening 20 are close to perpendicular to the substrate surface, the channel length L is shorter.

The channel width W of the transistor 10 is equal to the perimeter of the opening 20. When the top surface shape of the opening 20 is a circular shape as illustrated in FIG. 1A and the diameter is R, the channel width W of the transistor 10 is equal to the circumference of the opening 20, i.e., the channel width W is π×R. When the top surface shape of the opening 20 is a circular shape, the channel width W of the transistor can be the smallest.

Actually, the diameter of the opening 20 changes with depth in many cases. In this case, the average value of the diameters at three points corresponding to the highest, lowest, halfway points at the insulating layer 28 in a cross-sectional view can be used as the diameter of the opening 20. Without being limited to the above, the diameter of the opening 20 may be any of the diameters at the three points corresponding to the highest, lowest, halfway points at the insulating layer 28.

Note that although the opening 20 has a circular shape in the above, there is no limitation and a variety of shapes can be employed. Besides the circular shape, for example, an elliptical shape or a quadrangular shape with rounded corners can be employed. Alternatively, a regular polygonal shape such as a regular triangular shape, a square shape, or a regular pentagonal shape or a polygonal shape other than the regular polygonal shape may be employed. By employing a concave polygonal shape in which at least one interior angle is greater than 180°, such as a star polygonal shape, the channel width can be increased.

As illustrated in FIG. 2A, in the opening 20, the side surfaces of the insulating layer 28, the insulating layer 29a, and the insulating layer 29b are inclined upward, i.e., the side surfaces have so-called tapered shapes. Here, when the angle between the side surface of the insulating layer 28 in the opening 20 and the top surface of the insulating layer 24 at the bottom of the opening 20 is denoted by an angle θ, it is preferable that the angle θ have a portion greater than or equal to 90° and less than or equal to 135°, preferably less than or equal to 125°, further preferably less than or equal to 120°, still further preferably less than or equal to 110°. As the angle θ is closer to 90°, i.e., the slope of the side surface of the insulating layer 28 is close to perpendicular to the substrate surface, the area occupied by the transistor 10 can be reduced. Note that in the case where a stack of the semiconductor layer 21, the insulating layer 22, and the conductive layer 23 can cover the side surface of the insulating layer 28, the angle θ may be less than 90°.

The semiconductor layer 21 is deposited along the side surfaces of the insulating layers 29a, 28, and 29b in the opening. At this time, if film deposition is performed by a deposition method such as a sputtering method or a plasma CVD method, a film deposited on a surface inclined with respect to the substrate surface or a surface perpendicular to the substrate surface tends to be thinner than a film deposited on a surface horizontal to the substrate surface. Thus, when the semiconductor layer 21 is formed by a sputtering method, portions in contact with the insulating layer 28 may be thinner than portions in contact with the top surface of the conductive layer 24 and portions in contact with the top surface of the insulating layer 29b.

In a manner similar to the above, the insulating layer 22 and the conductive layer 23 may be deposited so that portions deposited along the side surface of the insulating layer 28 or the like in the opening are thinner than portions formed over the top surfaces of the conductive layer 24 and the insulating layer 29b.

Meanwhile, a film deposited by an ALD method or the like can have a uniform thickness regardless of the tilt angle of a formation surface, so that thickness variation hardly occurs in the semiconductor layer 21, the insulating layer 22, the conductive layer 23, and the like.

Here, with use of a light-blocking conductive material for one or both of the conductive layer 23 and the conductive layer 24, light reaching a channel formation region of the semiconductor layer 21 can be blocked; thus, the reliability of the transistor 10 can be increased. In particular, variations in the threshold voltage in an NBTIS test can be small. It is preferable to use a light-blocking conductive material for at least one of the conductive layer 23 and the conductive layer 24, which is a conductive layer on the side where a backlight is provided. Furthermore, it is preferable to use a light-blocking conductive material for both the conductive layer 23 and the conductive layer 24, in which case the influence of light can be reduced more effectively.

Although described above is an example in which the semiconductor layer 21, the insulating layer 22, and the conductive layer 23 are provided to cover the entire opening 20 in a plan view, one embodiment of the present invention is not limited to this example. For example, a structure in which the semiconductor layer 21, the insulating layer 22, and the conductive layer 23 are stacked along at least a portion of the side surface of the insulating layer 28 may be employed. For another example, the semiconductor layer 21 and the conductive layer 23 may be provided such that one or both of the semiconductor layer 21 and the conductive layer 23 cover a portion of the opening 20 and do not cover another portion thereof. For another example, a structure in which the opening 20 has a long thin groove shape (slit shape), and one or both of the semiconductor layer 21 and the conductive layer 23 cover a portion of the opening 20 with the groove shape and do not cover another portion thereof may be employed. Alternatively, a structure in which one or both of the semiconductor layer 21 and the conductive layer 23 are provided to straddle the opening 20 with the groove shape may be employed.

The display device of one embodiment of the present invention with such a structure can be a liquid crystal display device with an extremely high aperture ratio.

FIG. 2B illustrates an example of a transistor 10a that can be formed over the same plane as the transistor 10. The transistor 10a is different from the transistor 10 mainly in that it includes a conductive layer 31.

The conductive layer 31 functions as the other of the source electrode and the drain electrode of the transistor 10a. The conductive layer 31 is provided over the insulating layer 29b, and the semiconductor layer 21 is provided in contact with the top surface of the conductive layer 31. Accordingly, a conductive material that is less likely to be oxidized, a conductive material that maintains low electric resistance even after being oxidized, or an oxide conductive material is preferably used for the portion of the conductive layer 31 that is in contact with the semiconductor layer 21, similarly to the conductive layer 24. The conductive layer 31 can be formed using a conductive material similar to that of the conductive layer 24.

The conductive layer 31 preferably has lower resistance than the semiconductor layer 21. In the case where a relatively high-resistance material such as a metal oxide is used for the conductive layer 31, for example, it is preferable that the thickness be greater than that of the semiconductor layer 21 so that the resistance of the conductive layer 31 is lower than that of the semiconductor layer 21. The conductive layer 31 has lower resistance than the semiconductor layer 21 and thus can be used as a wiring.

The transistor 10 can be used as a transistor connected to the pixel electrode of the pixel. Meanwhile, the transistor 10a can be used in circuits other than the pixel circuit, such as a scan line driver circuit, a signal line driver circuit, and a protection circuit.

The transistor 10 and the transistor 10a can separately be formed through the same process. For example, with the use of a mask pattern for processing the conductive layer 31, the transistor 10a including the conductive layer 31 and the transistor 10 not including the conductive layer 31 may separately be formed.

### Variation Examples

A structure example whose structure is partly different from that of the above structure example will be described below. Note that the description of portions that are the same as those described above may be omitted in the following description.

### Modification Example 1

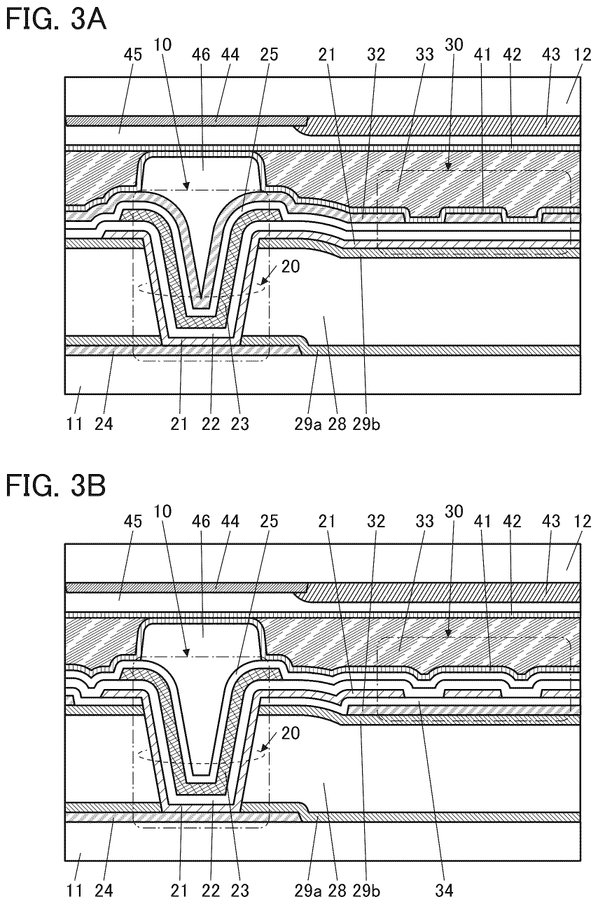

A structure illustrated in FIG. 3A is different from that in the above structure example mainly in the shape of the conductive layer 32.

In the above structure example, an opening is provided in a portion of the conductive layer 32 overlapping with the opening 20 in order that the conductive layer 32 does not overlap with the opening 20; however, the conductive layer 32 is provided to overlap with the opening 20 in FIG. 3A. The conductive layer 32 includes a portion positioned between the insulating layer 25 and the insulating layer 46.

In this way, the conductive layer 32 formed to cover the transistor 10 can be used as a shield that prevents transmission of an electrical noise input from the substrate 12 side to the transistor 10. In the case where an electrode of a touch sensor is provided over the substrate 12, for example, an electrical noise caused by a signal supplied to the electrode can be prevented from being transmitted to the transistor 10, the conductive layer 23 functioning as a scan line, the conductive layer 24 functioning as a signal line, and the like.

### Modification Example 2

A structure illustrated in FIG. 3B is different from that in the above-described structure example mainly in that the conductive layer 32 is positioned closer to the substrate 11 side than the semiconductor layer 21 is.

The conductive layer 32 is provided over the insulating layer 29b, an insulating layer 34 is provided to cover the conductive layer 32, and the semiconductor layer 21 is provided over the insulating layer 34. The insulating layer 22, the insulating layer 25, and the alignment film 41 are provided to cover the semiconductor layer 21.

A portion where the semiconductor layer 21, the insulating layer 34, and the conductive layer 32 are stacked functions as a storage capacitor, and a portion of the insulating layer 34 functions as a dielectric of the capacitor. An insulating material having a higher permittivity than silicon oxide, for example, is preferably used for the insulating layer 34. An insulating material that can be used for the insulating layer 29a, for example, can be used for the insulating layer 34.

In the structure illustrated in FIG. 3B, the insulating layer 34 that functions as a dielectric of the storage capacitor can be formed separately from the insulating layer 22 and the insulating layer 25, in which case the thickness and material of the insulating layer 34 can be optimized.

It is preferable that a film from which hydrogen is released by the above-described heating be used as at least the portion of the insulating layer 34 that is in contact with the semiconductor layer 21. In that case, the resistance of the portion of the semiconductor layer 21 functioning as the pixel electrode can be reduced.

### Modification Example 3

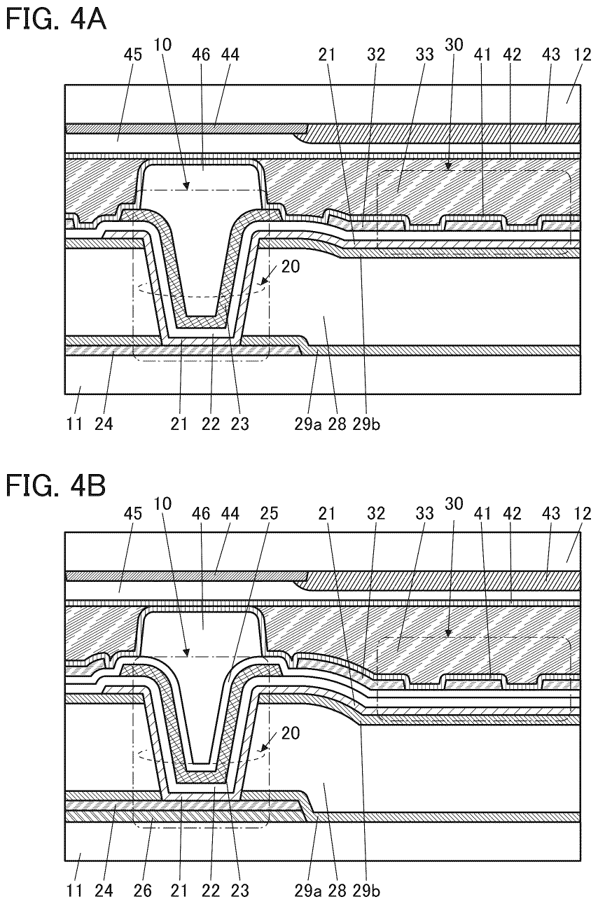

A structure illustrated in FIG. 4A is different from that in the above-described structure examples mainly in that the conductive layer 32 is provided over and in contact with the insulating layer 22.

The insulating layer 22 includes a portion in contact with the conductive layer 23 and a portion in contact with the conductive layer 32. In other words, the conductive layer 23 and the conductive layer 32 can be regarded as being formed on the same film formation surface (specifically, a top surface of the insulating layer 22).

Although the conductive layer 23 and the conductive layer 32 can be formed with the same light-transmitting conductive film, the conductive layer 23 is preferably formed with a conductive material having a lower resistance than that of the conductive layer 32. In that case, either the conductive layer 23 or the conductive layer 32 may be formed first. The conductive layer 23 may have a structure in which a light-transmitting conductive film used for the conductive layer 32 and a conductive film having a lower resistance are stacked.

It is also possible that part of the conductive layer 32 overlaps with the conductive layer 23. In this way, even when the etching selectivity between the conductive layer 23 and the conductive layer 32 cannot be high, the conductive layer 23 and the conductive layer 32 can be processed without problems. For example, the conductive layer 32 may be formed in the following manner: after the conductive layer 23 is formed, a conductive film to be the conductive layer 32 is formed, a resist mask is formed to cover a portion of the conductive film overlapping with the conductive layer 23, and then the conductive film is etched. A structure is preferable in which the end portion (side surface) of the conductive layer 23 is covered with a portion of the conductive layer 32, for example, since the conductive layer 23 is not exposed at the time when the conductive film to be the conductive layer 32 is etched.

### Modification Example 4

A structure illustrated in FIG. 4B is different from that in the above-described structure examples mainly in that a conductive layer 26 is provided between the conductive layer 24 and the substrate 11.

As mentioned above, a conductive material that is less likely to be oxidized, a conductive material that maintains low electric resistance even after being oxidized, or an oxide conductive material is preferably used for the conductive layer 24 in the case where an oxide semiconductor is used for the semiconductor layer 21. Furthermore, the conductive layer 24 preferably has low resistance because it also functions as a signal line. Therefore, a conductive material that is less likely to be oxidized, a conductive material that maintains low electric resistance even after being oxidized, or an oxide conductive material is preferably used for at least the portion of the conductive layer 24 which is in contact with the semiconductor layer 21, and a conductive material with low resistance is preferably used for the other portions.

Although FIG. 4B illustrates an example in which the conductive layer 24 is stacked over the conductive layer 26 and end portions thereof are substantially aligned with each other, one embodiment of the present invention is not limited to this structure as long as the conductive layer 26 and the conductive layer 24 are electrically connected to each other. For example, in a portion of the conductive layer 24 other than the portion of the conductive layer 24 in contact with the semiconductor layer 21, the conductive layer 26 may be provided in contact with a top surface or a bottom surface of the conductive layer 24.

### Modification Example 5

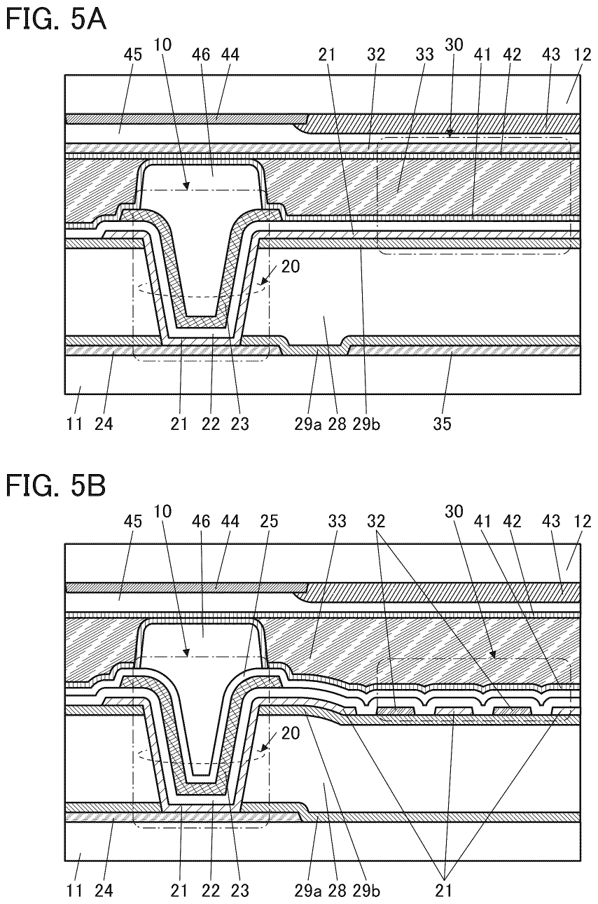

A structure illustrated in FIG. 5A is an example in which the liquid crystal element 30 in a VA mode is employed.

The conductive layer 32 is provided on the substrate 12 side. More specifically, the conductive layer 32 is provided between the insulating layer 45 and the alignment film 42.

Furthermore, a conductive layer 35 is provided between the substrate 11 and the insulating layer 29a. It is preferable that the conductive layer 35 be formed by processing the same conductive film as the conductive layer 24 and have a light-transmitting property. A storage capacitor is formed by the conductive layer 35, the semiconductor layer 21, and the insulating layer 29a, the insulating layer 28, and the insulating layer 29b provided between the conductive layer 35 and the semiconductor layer 21. In the structure illustrated in FIG. 5A, the conductive layer 35 and the conductive layer 24 are formed in the same step, which is preferable because the storage capacitor can be provided without an increase in the number of manufacturing steps.

### Modification Example 6

FIG. 5B illustrates an example in which the liquid crystal element 30 in an IPS mode is employed.

Each of the semiconductor layer 21 and the conductive layer 32 is provided over the insulating layer 29b. In that case, the semiconductor layer 21 and the conductive layer 32 are preferably formed by processing the same conductive film.

The semiconductor layer 21 and the conductive layer 32 each have a comb-like top surface shape and are arranged to be engaged with each other without being in contact with each other. In FIG. 5B, the semiconductor layer 21 and the conductive layer 32 are shown with different hatching patterns for clarity.

### Modification Example 7

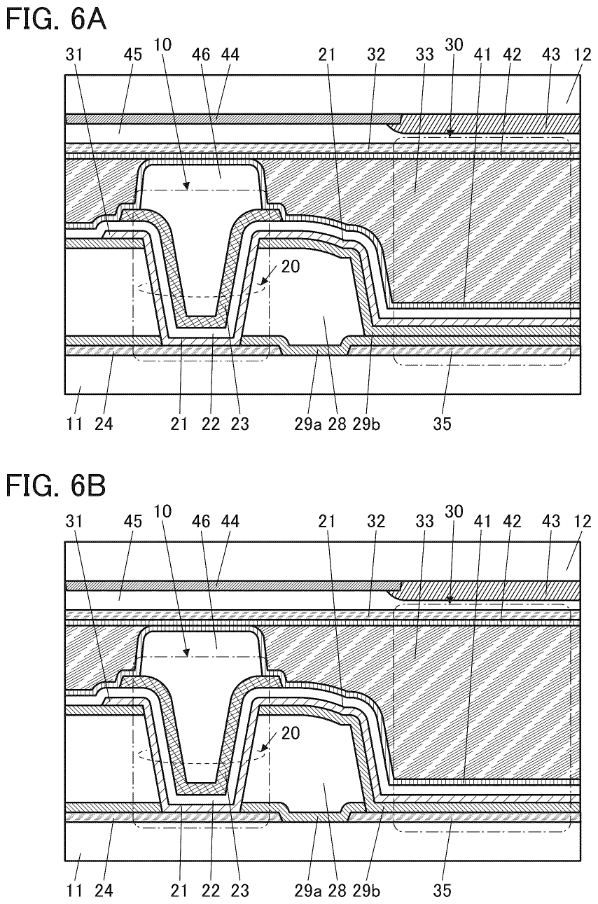

A structure example illustrated in FIG. 6A is a modification example of FIG. 5A.

In FIG. 6A, a portion of the insulating layer 28 overlapping with the liquid crystal element 30 is removed by etching. In other words, the structure illustrated in FIG. 6A includes a portion where the conductive layer 35, the insulating layer 29a, the insulating layer 29b, and the semiconductor layer 21 are stacked in this order. Thus, the capacitance between the conductive layer 35 and the semiconductor layer 21 can be higher than that in the structure illustrated in FIG. 5A. Furthermore, a portion functioning as the liquid crystal element 30 is not provided with the insulating layer 28, which enables not only an increase in the light transmittance but also a reduction in the number of interfaces positioned on the path of light from the light source; accordingly, the influences of interface reflection and interface scattering can be inhibited.

Note that as illustrated in FIG. 6B, not only the insulating layer 28 but also the portion of the insulating layer 29a overlapping with the liquid crystal element 30 may be etched. In that case, the capacitance between the conductive layer 35 and the semiconductor layer 21 can be further increased, the light transmittance can be improved, and the influence of interface reflection and interface scattering can be further reduced.

### Modification Example 8

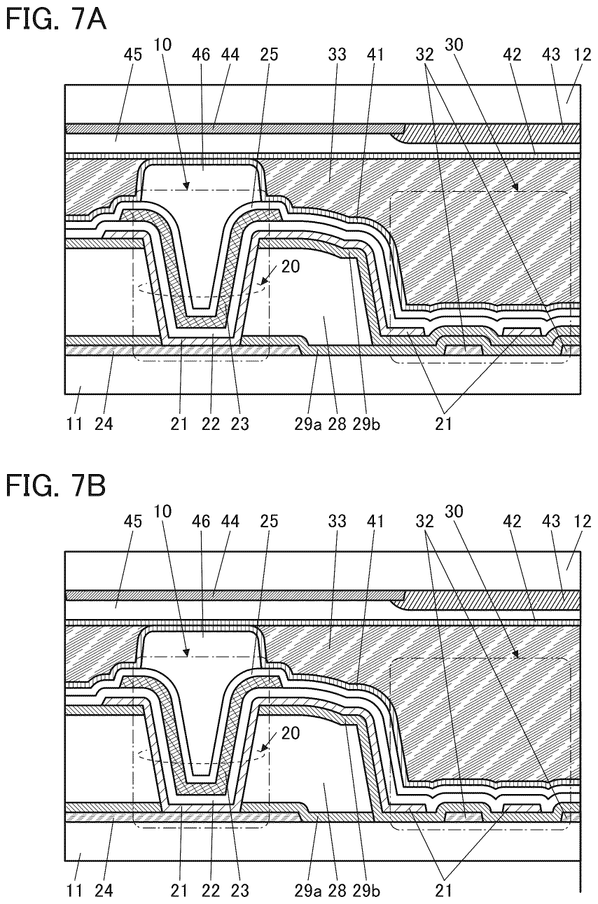

FIG. 7A illustrates a modification example of FIG. 3B.

In FIG. 7A, the conductive layer 32 in FIG. 3B is formed with the same conductive film as the conductive layer 24. In addition, a portion of the insulating layer 28 overlapping with the liquid crystal element 30 is removed by etching. Thus, the conductive layer 24 and the conductive layer 32 can be formed in the same step, so that the process can be simplified. Furthermore, as in Modification example 7, the insulating layer 28 is not provided, which not only can increase the light transmittance but also can inhibit influences of interface reflection and interface scattering.

Note that in FIG. 7A, a portion of either one or each of the insulating layer 22 and the insulating layer 25 overlapping with the liquid crystal element 30 may be removed by etching. Alternatively, the insulating layer 25 may not necessarily be provided. This facilitates transmission of the electric fields of the semiconductor layer 21 and the conductive layer 32 to the liquid crystal 33, which enables high-speed operation of the liquid crystal element 30. Furthermore, the light transmittance of a portion overlapping with the liquid crystal element 30 can be increased and the influences of interface reflection and interface scattering can be inhibited.

A portion of either one of the insulating layer 29a and the insulating layer 29b overlapping with the liquid crystal element 30 may be removed by etching. This also facilitates transmission of the electric fields of the semiconductor layer 21 and the conductive layer 32 to the liquid crystal 33. Furthermore, the capacitance between the semiconductor layer 21 and the conductive layer 32 can be increased in some cases. FIG. 7B illustrates an example in which the portion of the insulating layer 29a overlapping with the liquid crystal element 30 is removed by etching.

### Modification Example 9

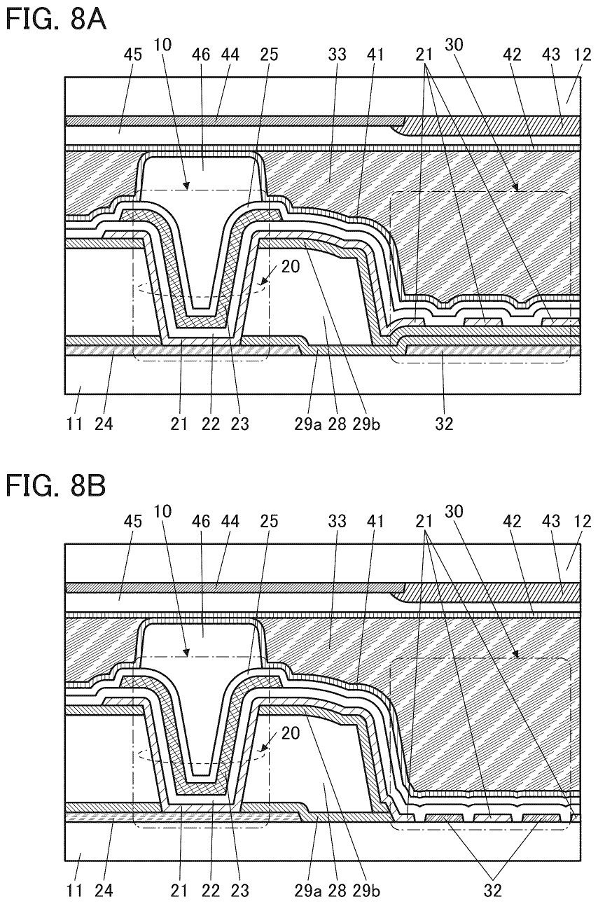

FIG. 8A illustrates a modification example of FIG. 7A.

FIG. 7A illustrates the case where each of the semiconductor layer 21 and the conductive layer 32 has a comb-like top surface shape, and FIG. 8A illustrates a structure in which only the semiconductor layer 21 has a comb-like shape and the semiconductor layer 21 and the conductive layer 32 overlap with each other. With this structure, the capacitance between the semiconductor layer 21 and the conductive layer 32 can be used as a storage capacitor and an additional capacitor is not needed; thus, a display device with a high aperture ratio is achieved. In that case, a portion of either one of the insulating layer 29a and the insulating layer 29b that overlaps with the semiconductor layer 21 is preferably removed by etching because the capacitance can be increased. For the same reason as above, the portion of either one or each of the insulating layer 22 and the insulating layer 25 that overlaps with the liquid crystal element 30 may be removed by etching, or the insulating layer 25 is not necessarily provided if not needed.

### Modification Example 10

The structure illustrated in FIG. 8B is a modification example of FIG. 5B and FIG. 7A.

In FIG. 8B, regions of the insulating layer 29a and the insulating layer 29b where the insulating layer 28 is not provided are removed by etching, and the semiconductor layer 21 and the conductive layer 32 are formed on the same plane. Although the semiconductor layer 21 and the conductive layer 32 are shown with different hatching patterns here, as in FIG. 5B, the semiconductor layer 21 and the conductive layer 32 may be formed by processing the same conductive film. Alternatively, the conductive layer 32 may be formed by processing the same conductive film as the conductive layer 24.

The portion of either one or each of the insulating layer 22 and the insulating layer 25 that overlaps with the liquid crystal element 30 may be removed by etching, or the insulating layer 25 is not necessarily provided if not needed.

### Pixel Structure Example

A structure example of a pixel where a vertical transistor of one embodiment of the present invention is used will be described below.

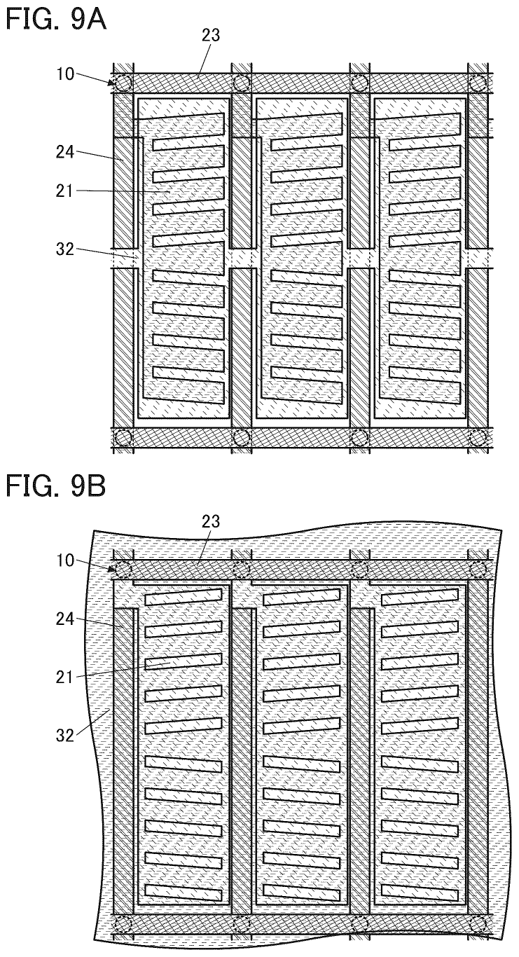

FIG. 9A is a schematic top view of a pixel. FIG. 9A illustrates three subpixels arranged alongside. The three subpixels correspond to, for example, three colors including red (R), green (G), and blue (B), and have the same structures except for a coloring layer that transmits light of the corresponding color and absorbs light of the other colors.

Each of the subpixels is disposed at an intersection portion between the conductive layer 23 functioning as a scan line and the conductive layer 24 functioning as a signal line. The subpixel includes the transistor 10, the portion of the semiconductor layer 21 functioning as a pixel electrode, the conductive layer 32 functioning as a common electrode, and the like. The transistor 10 is provided at an intersection portion between the conductive layer 23 and the conductive layer 24.

The structure illustrated in FIG. 9A corresponds to the stacked structure illustrated in FIG. 3B, in which the conductive layer 32 functioning as a common electrode is positioned closer to the substrate 11 side than the semiconductor layer 21 functioning as a pixel electrode is. For clarity, in FIG. 9A, the semiconductor layer 21 is shown with a hatching pattern through which a layer positioned under the semiconductor layer 21 (on the substrate 11 side) can be seen.

The semiconductor layer 21 has a comb-like shape in the plan view. Sides of the projecting portions of the comb-like shape of the semiconductor layer 21 are preferably oblique to the extending direction of the conductive layer 23 and the extending direction of the conductive layer 24, as illustrated in FIG. 9A. The semiconductor layer 21 has a shape where the direction of the projecting portions is symmetric with respect to the extending direction of the conductive layer 24 (horizontally symmetrical shape in the drawing). Such a structure can increase the viewing angle characteristics of the display device such as luminance and chromaticity.

Although the case where the semiconductor layer 21 has a comb-like shape is described here, the shape of the semiconductor layer 21 is not limited to this as long as a portion where the semiconductor layer 21 and the conductive layer 32 are stacked and a portion where the semiconductor layer 21 is not provided over the conductive layer 32 are arranged alternately. The semiconductor layer 21 may have a shape with a plurality of opening portions, for example.

A portion of the conductive layer 32 has a portion overlapping with the conductive layer 24, and owing to this portion, the conductive layer 32 is continuous between subpixels arranged in the extending direction of the conductive layer 23. In this manner, the conductive layer 32 is preferably continuous between the subpixels by not including a portion overlapping with the conductive layer 23 but including a portion overlapping with the conductive layer 24. The conductive layer 32 and the conductive layer 24 overlap with each other through the insulating layer 28 functioning as a spacer or the like as in FIG. 3B and the like, in which case the parasitic capacitance can be lower than that in the case where the conductive layer 32 and the conductive layer 23 overlap with each other. Furthermore, an area where the conductive layer 32 and the conductive layer 24 overlap with each other is preferably as small as possible as illustrated in FIG. 9A, in which case the parasitic capacitance between these layers can be further reduced.

The semiconductor layer 21 is placed such that the area overlapping with the conductive layer 23 is smaller than the area overlapping with the conductive layer 24. In this way, parasitic capacitance between the semiconductor layer 21 and the conductive layer 23 can be effectively reduced.

FIG. 9B illustrates an example in which the positions of the semiconductor layer 21 and the conductive layer 32 in FIG. 9A are turned upside down. For example, the structure of FIG. 9B corresponds to the structure of FIG. 3A. In FIG. 9B, the hatching patterns of the semiconductor layer 21 and the conductive layer 32 in FIG. 9A are switched.

The conductive layer 32 is provided with a plurality of slits (also referred to as openings) overlapping with the semiconductor layer 21. The directions of long sides of these slits are oblique to the extending direction of the conductive layer 23 and the extending direction of the conductive layer 24. The directions of the long sides of the slits are preferably linearly symmetric with respect to the center portion of the semiconductor layer 21 in the extending direction of the conductive layer 24. Thus, the viewing angle characteristics can be improved.

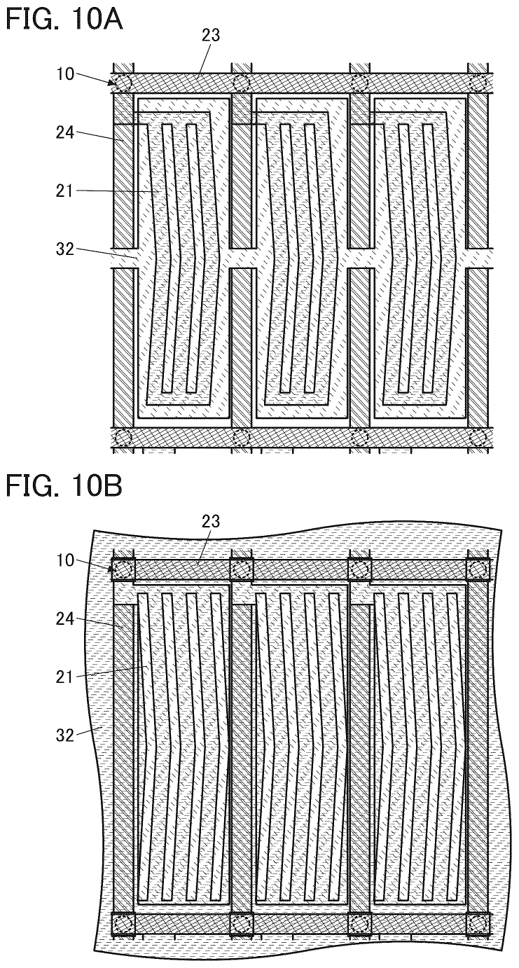

FIG. 10A is different from the structure illustrated in FIG. 9A mainly in the shape of the semiconductor layer 21.

In FIG. 10A, the semiconductor layer 21 is provided with a plurality of slits. The longitudinal direction of the slits is parallel to the longitudinal direction of a subpixel, here, the extending direction of the conductive layer 24. Here, it is preferable that the shape of the slits be not rectangular but have a dog-leg shape (V-shape) where a portion of a rectangle is curved. Thus, the viewing angle characteristics can be improved.

FIG. 10B illustrates an example in which the shape of the conductive layer 32 in FIG. 9B is changed. The conductive layer 32 in FIG. 10B is provided with slits similar to those of the semiconductor layer 21 in FIG. 10A.

An example of a pixel that can be used in a liquid crystal display device with higher definition will be described below.

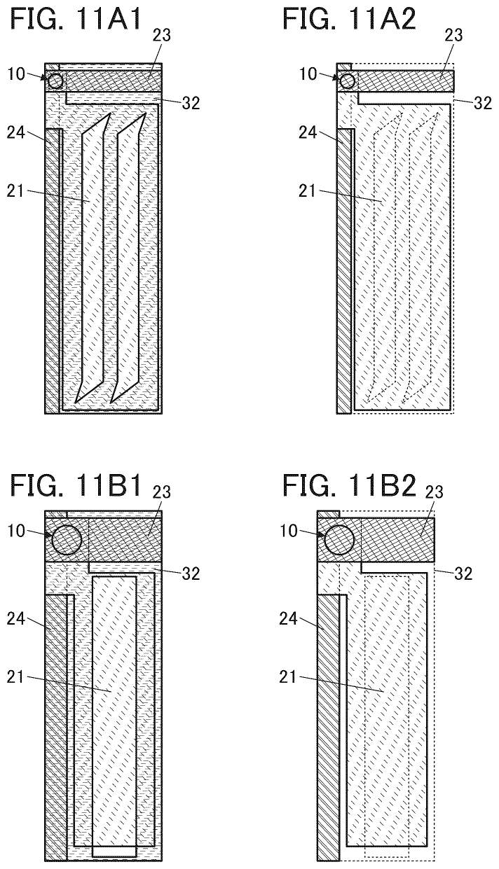

FIG. 11A1 is a modification example of the structure illustrated in FIG. 10B. Here, a schematic top view of one subpixel is illustrated. FIG. 11A2 is a diagram in which only the outline of the conductive layer 32 in FIG. 11A1 is indicated by a dashed line.

The conductive layer 32 includes two slits in a region overlapping with the semiconductor layer 21. These slits each have a shape whose longitudinal direction is along the extending direction of the conductive layer 24, and are arranged next to each other in the extending direction of the conductive layer 23. Each of the slits has a shape where an end portion in the longitudinal direction is sharpened in the oblique direction. Each slit has a shape symmetric with respect to 180° rotation. With such a shape, the area required for the placement of the slits can be reduced as compared with the case where a slit with a dog-leg shape (V-shape) that is illustrated as an example in FIG. 10B is used. Thus, a liquid crystal display device having both high viewing angle characteristics and high definition can be achieved.

The structure illustrated in FIG. 11A1, for example, can achieve a liquid crystal display device with a definition higher than or equal to 500 ppi even when the minimum feature size is 1.5 μm. With the subpixel illustrated in FIG. 11A1, for example, the aperture ratio can be extremely high at approximately 64.3%, even with a definition of 513 ppi. Note that in the case where a lateral transistor with a top-gate structure is used, the aperture ratio with the same definition is approximately 56.0%.

The structure illustrated in FIG. 11B1 is a modification example of the structure illustrated in FIG. 11A1. FIG. 11B2 is a diagram in which only the outline of the conductive layer 32 in FIG. 11B2 is indicated by a dashed line.

The conductive layer 32 includes one slit. The slit has a rectangular shape whose longitudinal direction is along the extending direction of the conductive layer 24. With such a shape of the slit, an extremely minute pixel can be formed.

Along with miniaturization, the wiring width of the conductive layer 24 is smaller than the diameter of the opening that forms the transistor 10. In this way, when the wiring along the longitudinal direction of the subpixel is made thin, the aperture ratio can be kept high even in a minute pixel. Meanwhile, the wiring width of the conductive layer 23 which is orthogonal to the conductive layer 24 is preferably larger than the diameter of the opening, in which case the wiring resistance can be reduced.

The structure illustrated in FIG. 11B1, for example, can achieve a liquid crystal display device with a definition higher than or equal to 1000 ppi even when the minimum feature size is 1.5 μm. With the subpixel illustrated in FIG. 11B1, for example, the aperture ratio can be extremely high at approximately 52.3%, even with a definition of 1058 ppi. Note that in the case where a lateral transistor with a top-gate structure is used, the aperture ratio with the same definition is approximately 41.1%.

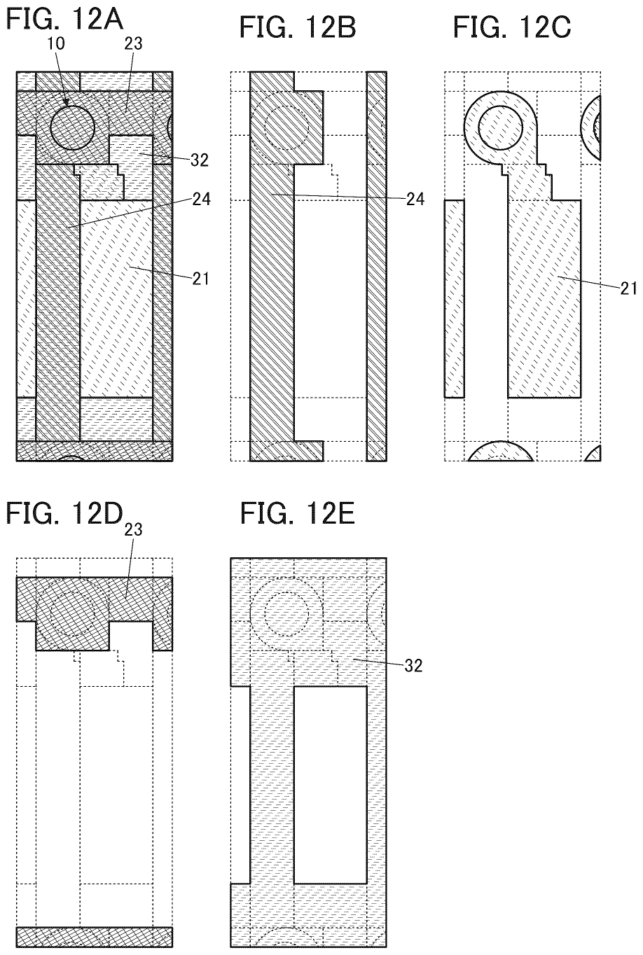

The structure illustrated in FIG. 12A is a modification example of the structure illustrated in FIG. 11B1. FIG. 12B, FIG. 12C, FIG. 12D, and FIG. 12E illustrate only the conductive layer 24, the semiconductor layer 21, the conductive layer 23, and the conductive layer 32, respectively.

With further miniaturization, the conductive layer 23 and the conductive layer 24 each have a shape where a portion in which an opening that forms the transistor 10 is provided is wide and the remaining portions are narrowed. Such a shape can ensure a high aperture ratio even in an extremely minute subpixel.

Here, an example in which a portion of the outline of the semiconductor layer 21 around the transistor 10 is curved (here, arc) is illustrated. By using a pattern with a curved outline as in this example, the layout design flexibility is increased as compared with the case where only a straight line is used; thus, patterns can be arranged with higher density. As a result, a display device with a high aperture ratio even with a high definition can be achieved.

The structure illustrated in FIG. 12A, for example, can achieve a display device with a definition higher than or equal to 2000 ppi even when the minimum feature size is 1.5 μm. The aperture ratio of the subpixel illustrated in FIG. 12A, for example, is approximately 35.3%.

The above is the description of the structure examples of the pixels.

In one embodiment of the present invention, a vertical transistor whose footprint can be extremely small is used in a pixel of a liquid crystal display device, and a portion of a semiconductor layer also serves as a pixel electrode, whereby a liquid crystal display device with extremely high definition and a high aperture ratio can be achieved. Furthermore, the vertical transistor of one embodiment of the present invention can have a shorter channel length and can flow a larger amount of current than a conventional lateral transistor. Thus, with use of such transistors for a display device, a liquid crystal display device capable of high-speed operation and high-quality display can be achieved. In addition, the vertical transistor of one embodiment of the present invention has an extremely low leakage current in an off state even though having a short channel length, thus, use of the transistor for a liquid crystal display device enables a potential written to a pixel to be retained for a long time, leading to display with a low frame rate and reduction of power consumption.

At least part of this embodiment can be implemented in combination with the other embodiments described in this specification as appropriate.

### Embodiment 2

In this embodiment, structure examples of a display device of one embodiment of the present invention will be described.

The display device in this embodiment can be a high-resolution display device or large-sized display device. Accordingly, the display device in this embodiment can be used for display portions of electronic devices such as a digital camera, a digital video camera, a digital photo frame, a mobile phone, a portable game console, a portable information terminal, and an audio reproducing device, in addition to display portions of electronic devices with a relatively large screen, such as a television device, a desktop or laptop personal computer, a monitor of a computer or the like, digital signage, and a large game machine such as a pachinko machine.

The display device in this embodiment can be a high-resolution display device. Accordingly, the display device in this embodiment can be used for display portions of information terminals (wearable devices) such as watch-type and bracelet-type information terminals and display portions of wearable devices capable of being worn on the head, such as a VR device like a head-mounted display (HMD) and a glasses-type AR device.

The semiconductor device of one embodiment of the present invention can be used for a display device or a module including the display device. Examples of the module including the display device include a module in which a connector such as a flexible printed circuit board (hereinafter referred to as an FPC) or a TCP (Tape Carrier Package) is attached to the display device and a module in which the display device is mounted with an integrated circuit (IC) by a COG (Chip On Glass) method, a COF (Chip On Film) method, or the like.

### Structure Example of Display Device

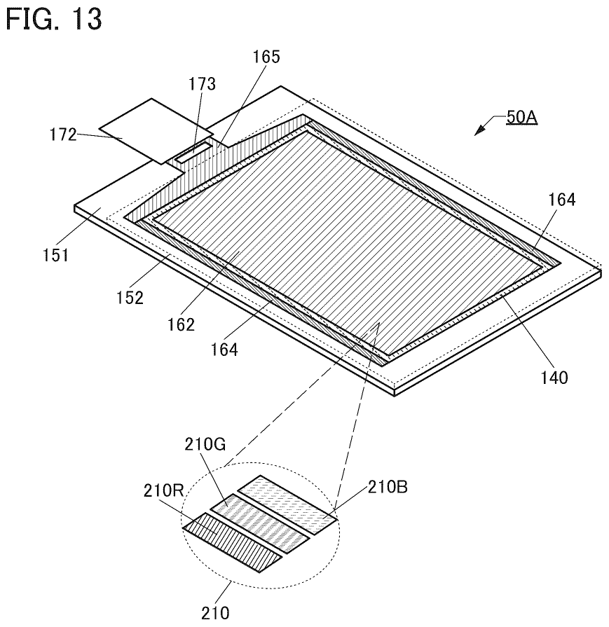

FIG. 13 is a perspective view of a display device 50A.

In the display device 50A, a substrate 152 and a substrate 151 are bonded to each other. In FIG. 13, the substrate 152 is indicated by a dashed line.

The display device 50A includes a display portion 162, a connection portion 140, a circuit portion 164, a wiring 165, and the like. FIG. 13 illustrates an example where an IC 173 and an FPC 172 are implemented onto the display device 50A. Thus, the structure illustrated in FIG. 13 can be regarded as a display module including the display device 50A, the IC, and the FPC.

The connection portion 140 is provided outside the display portion 162. The connection portion 140 can be provided along one or more sides of the display portion 162. The number of connection portions 140 may be one or more. FIG. 13 illustrates an example in which the connection portion 140 is provided to surround the four sides of the display portion 162. In the connection portion 140, a common electrode of a display element is electrically connected to a conductive layer so that a potential can be supplied to the common electrode. Note that the connection portion 140 is not necessarily provided if not needed, for example, in the case where the common electrode is provided on the substrate 151 side.

The circuit portion 164 includes a scan line driver circuit (also referred to as a gate driver), for example. The circuit portion 164 may include both a scan line driver circuit and a signal line driver circuit (also referred to as a source driver).

The wiring 165 has a function of supplying a signal and power to the display portion 162 and the circuit portion 164. The signal and power are input to the wiring 165 from the outside through the FPC 172, or input to the wiring 165 from the IC 173.

FIG. 13 illustrates an example where the IC 173 is provided on the substrate 151 by a COG method, a COF method, or the like. An IC including one or both of a scan line driver circuit and a signal line driver circuit can be used as the IC 173, for example. Note that the display device 50A and the display module are not necessarily provided with an IC. The IC may be mounted on the FPC by a COF method or the like.

The vertical transistor of one embodiment of the present invention can be used for one or both of the display portion 162 and the circuit portion 164 of the display device 50A, for example. The vertical transistor of one embodiment of the present invention can also be used for the IC 173. A structure where the vertical transistor of one embodiment of the present invention is provided over a silicon wafer can be employed, for example. In that case, it is preferable to form the circuit using two types of transistors, in which a transistor including single crystal silicon in a semiconductor layer is provided and the vertical transistor of one embodiment of the present invention is stacked above the transistor.

When the vertical transistor of one embodiment of the present invention is used for a pixel circuit of the display device, the area occupied by the pixel circuit can be reduced as compared with a case where a planar transistor is used, and the display device can have high definition, for example. When the vertical transistor of one embodiment of the present invention is used for a driver circuit (e.g., one or both of a gate line driver circuit and a source line driver circuit) of the display device, the area occupied by the driver circuit can be reduced as compared with a case where a planar transistor is used, and the display device can have a narrow bezel, for example. Since the vertical transistor of one embodiment of the present invention has favorable electrical characteristics, a display device can have increased reliability by using the vertical transistor.

The display portion 162 is a region where an image is displayed and a plurality of pixels 210 are periodically arranged in the display device 50A. FIG. 13 shows an enlarged view of one pixel 210.

There is no particular limitation on the arrangement of pixels in the display device of one embodiment of the present invention, and a variety of arrangements can be employed. Examples of the arrangement of pixels include stripe arrangement, S-stripe arrangement, matrix arrangement, delta arrangement, Bayer arrangement, and PenTile arrangement.

The pixel 210 illustrated in FIG. 13 includes a subpixel 210R that emits red light, a subpixel 210G that emits green light, and a subpixel 210B that emits blue light. The subpixels 210R, 210G, and 210B each include a display element and a circuit for controlling the driving of the display element.

As the display element, a liquid crystal element can be used, for example. In that case, a transmissive liquid crystal display device, a reflective liquid crystal display device, or a transflective liquid crystal display device can be obtained, for example.

In addition to a liquid crystal element, various elements (e.g., a light-emitting element) can be used as a display element. As the light-emitting element, a self-luminous light-emitting element such as an LED (Light Emitting Diode), an OLED (Organic LED), or a semiconductor laser can be given. Examples of the LED include a mini LED and a micro LED.

Alternatively, a MEMS (Micro Electro Mechanical Systems) shutter element, an optical interference type MEMS element, or a display element using a microcapsule method, an electrophoretic method, an electrowetting method, an Electronic Liquid Powder (registered trademark) method, or the like can be used. Alternatively, a QLED (Quantum-dot LED) employing a light source and color conversion technology using quantum dot materials may be used.

### Cross-Sectional Structure Example 1

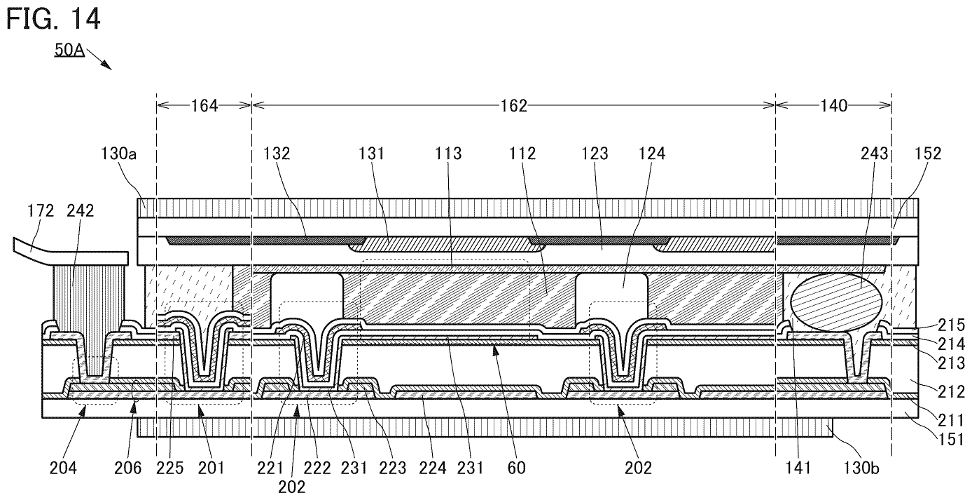

FIG. 14 illustrates an example of cross sections of part of a region including the FPC 172, part of the circuit portion 164, part of the display portion 162, part of the connection portion 140, and part of a region including an end portion of the display device 50A.

FIG. 14 is a schematic cross-sectional view in the case where a liquid crystal element in a VA mode is employed.

The substrate 151 and the substrate 152 are bonded to each other with an adhesive layer 141. A region surrounded by the substrate 151, the substrate 152, and the adhesive layer 141 is filled with liquid crystal 112. A polarizing plate 130a is provided on an outer surface of the substrate 152. A polarizing plate 130b is provided on an outer surface of the substrate 151.

Although not illustrated, a backlight can be provided outside the polarizing plate 130a or the polarizing plate 130b.

The substrate 151 is provided with a semiconductor layer 231 functioning as a pixel electrode of a liquid crystal element 60, a transistor 201, a plurality of transistors 202, a connection portion 204, a wiring 206, a spacer 124, and the like. The transistor 201 is provided in the circuit portion 164 and the transistors 202 are provided in subpixels.

The substrate 152 is provided with a coloring layer 131, a light-blocking layer 132, an insulating layer 123, a common electrode 113, and the like.

Insulating layers such as an insulating layer 211, an insulating layer 212, an insulating layer 213, an insulating layer 214, and an insulating layer 215 are provided over the substrate 151. The insulating layer 211, the insulating layer 212, and the insulating layer 213 function as interlayer insulating layers (or spacers). The insulating layer 214 partly functions as a gate insulating layer of the transistor 201 or the transistor 202. The insulating layer 215 has a function of a protective layer of the transistor 201 and the transistor 202.

Each of the transistor 201 and the transistor 202 includes a conductive layer 222, the semiconductor layer 231, a portion of the insulating layer 214, and a conductive layer 221. The semiconductor layer 231 of the transistor 202 functions as a portion of the pixel electrode. The conductive layer 222 functions as one of a source electrode and a drain electrode, and part of the conductive layer 231 functions as the other of the source electrode and the drain electrode. The conductive layer 221 functions as a gate electrode. The transistor 201 further includes a conductive layer 225. The conductive layer 225 functions as the other of the source electrode and the drain electrode.

The transistors described in Embodiment 1 can be used as the transistor 201 and the transistor 202; thus, description of the transistors in Embodiment 1 can be referred to for the detailed explanation. It is particularly preferable to use, as the transistor 201, the transistor 10a including both the source electrode and the drain electrode in addition to the semiconductor layer.

Here, a conductive layer 223 is provided over and in contact with the conductive layer 222. The conductive layer 223 contains a conductive material having a conductivity higher than that of the conductive layer 222 and functions as an auxiliary wiring. In the case where a conductive oxide is used for the conductive layer 222, it is sometimes difficult to use the conductive layer 222 as a wiring because of its high resistance. In such a case, the conductive layer 223 having a conductivity higher than that of the conductive layer 222 is provided to supplement the conductivity of the conductive layer 222. Note that although the structure in which the conductive layer 223 is provided over the conductive layer 222 is employed here, the conductive layer 223 may be provided below the conductive layer 222. Although not illustrated here, a conductive layer similar to the above is preferably provided in contact with the conductive layer 225.

The liquid crystal element 60 includes the portion of the semiconductor layer 231 functioning as a pixel electrode, the common electrode 113, and the liquid crystal 112 interposed therebetween.

Over the substrate 151, a conductive layer 224 positioned on the same plane as the conductive layer 222 is provided. The conductive layer 224 includes a portion overlapping with the semiconductor layer 231 with the insulating layer 211, the insulating layer 212, and the insulating layer 213 positioned therebetween. The semiconductor layer 231, the conductive layer 224, and the insulating layer positioned therebetween form a storage capacitor. Note that any one or two of the insulating layer 211, the insulating layer 212, and the insulating layer 213 may be removed by etching as long as at least one insulating layer is provided between the semiconductor layer 231 and the conductive layer 224.

FIG. 14 illustrates a cross section of two subpixels, as an example of the display portion 162. One of the subpixels at least includes the transistor 202, the liquid crystal element 60, and the coloring layer 131. For example, the coloring layers 131 are selectively formed so that a subpixel exhibiting a red color, a subpixel exhibiting a green color, and a subpixel exhibiting a blue color are arranged; thus, full-color display can be performed. Here, a pixel circuit (subpixel circuit) is composed of the transistor 202, the portion of the semiconductor layer 231 functioning as a pixel electrode, a wiring, and the like.

Although the case where the transistor 201 included in the circuit portion 164 and the transistor 202 included in the display portion 162 have different structures is shown here, they may have the same structure. A plurality of transistors included in the circuit portion 164 may all have the same structure, or transistors with different structures may be used in combination.

A material through which impurities such as water or hydrogen are less likely to be diffused is preferably used for the insulating layer 215 which covers the transistors. That is, the insulating layer 215 can function as a barrier film. Such a structure can effectively suppress diffusion of the impurities into the transistors from the outside, and a highly reliable touch panel can be provided.

The insulating layer 123 is provided on the substrate 152 side to cover the coloring layer 131 and the light-blocking layer 132. The insulating layer 123 may have a function of a planarization film. The insulating layer 123 enables the common electrode 113 to have an almost flat surface, resulting in a uniform alignment state of the liquid crystal 112.

Alignment films for controlling alignment of the liquid crystal 112 may be provided on surfaces of the semiconductor layer 231, the common electrode 113, the insulating layer 215, and the like which are in contact with the liquid crystal 112.

In the liquid crystal element 60, the semiconductor layer 231 and the common electrode 113 each have a function of transmitting visible light. By having such a structure, the display device in which the liquid crystal element 60 is used can be a transmissive liquid crystal display device. For example, in the case where a backlight is provided on the substrate 152 side, light from the backlight which is polarized by the polarizing plate 130a passes through the substrate 152, the common electrode 113, the liquid crystal 112, the semiconductor layer 231, and the substrate 151, and then reaches the polarizing plate 130b. In this case, alignment of the liquid crystal 112 is controlled with a voltage that is applied between the semiconductor layer 231 and the common electrode 113, and thus optical modulation of light can be controlled. That is, the intensity of light emitted through the polarizing plate 130b can be controlled. Light other than one in a particular wavelength region of the incident light is absorbed by the coloring layer 131, and thus, emitted light is red light, for example.

As the polarizing plate 130b, a linear polarizing plate or a circularly polarizing plate can be used. An example of a circularly polarizing plate is a stack including a linear polarizing plate and a quarter-wave retardation plate. Reflection of external light can be suppressed with a circularly polarizing plate used as the polarizing plate 130b.

In the case where a circularly polarizing plate is used as the polarizing plate 130b, a circularly polarizing plate may be also used as the polarizing plate 130a and a general linear polarizing plate may be used. The cell gap, alignment, driving voltage, and the like of the liquid crystal element used as the liquid crystal element 60 are controlled depending on the types of polarizing plates used as the polarizing plate 130a and the polarizing plate 130b so that desirable contrast is obtained.

The common electrode 113 is electrically connected to a conductive layer provided on the substrate 151 side through a connector 243 in the connection portion 140. Thus, a potential or a signal can be supplied from an FPC or an IC provided on the substrate 151 side to the common electrode 113.

As the connector 243, a conductive particle can be used, for example. As the conductive particle, a particle of an organic resin, silica, or the like coated with a metal material can be used. It is preferable to use nickel or gold as the metal material because contact resistance can be decreased. It is also preferable to use a particle coated with layers of two or more kinds of metal materials, such as a particle coated with nickel and further with gold. As the connector 243, a material capable of elastic deformation or plastic deformation is preferably used. As illustrated in FIG. 14, the conductive particle has a shape that is vertically crushed in some cases. With the crushed shape, the contact area between the connector 243 and a conductive layer electrically connected to the connector 243 can be increased, thereby reducing contact resistance and suppressing the generation of problems such as disconnection.

The connector 243 is preferably provided so as to be covered with the adhesive layer 141. For example, the connector 243 is dispersed in the adhesive layer 141 that is not yet cured. A structure in which the connector 243 is provided in a portion provided with the adhesive layer 141 can be applied to, for example, a structure in which the adhesive layer 141 is provided in the peripheral region, e.g., a display device with a solid sealing structure or a hollow sealing structure.

The connection portion 204 is provided in a region near an end portion of the substrate 151. In the connection portion 204, the wiring 206 is electrically connected to the FPC 172 through a connection layer 242. The wiring 206 in the structure illustrated in FIG. 14 has a stacked structure similar to the stacked structure of the conductive layer 222 and the conductive layer 223, for example.

It is preferable to use a conductive oxide for the conductive layer 225. Accordingly, favorable connection characteristics with the semiconductor layer 231 can be achieved. Furthermore, an electrode connected to the connector 243 in the connection portion 140 and an electrode connected to the connection layer 242 in the connection portion 204 are preferably formed using the same conductive film as the conductive layer 225 through the same process. Thus, occurrence of a contact defect, which is caused by exposed portions of the connection portion 140 and the connection portion 204 being oxidized to form an insulating film, can be prevented, and a highly reliable display device can be achieved.

### Cross-Sectional Structure Example 2

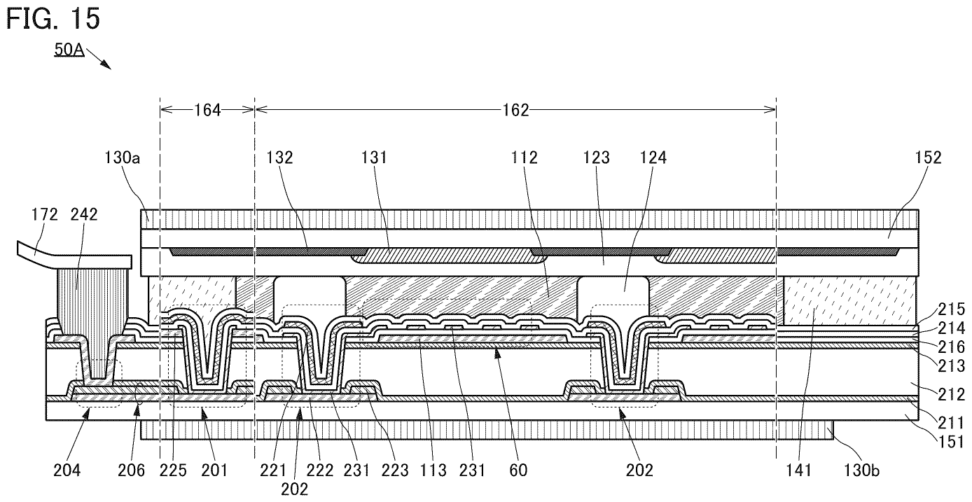

FIG. 15 is a schematic cross-sectional view of a display device including a liquid crystal element in an FFS mode.

The common electrode 113 is provided over the insulating layer 213, and an insulating layer 216 is provided over the common electrode 113. A portion of the semiconductor layer 231 is provided over the insulating layer 216.

In a plan view, the portion of the semiconductor layer 231 has a comb-like shape or a shape with a slit. The common electrode 113 is provided to overlap with the semiconductor layer 231. There is a portion where the semiconductor layer 231 is not provided over the common electrode 113 in a region overlapping with the coloring layer 131.

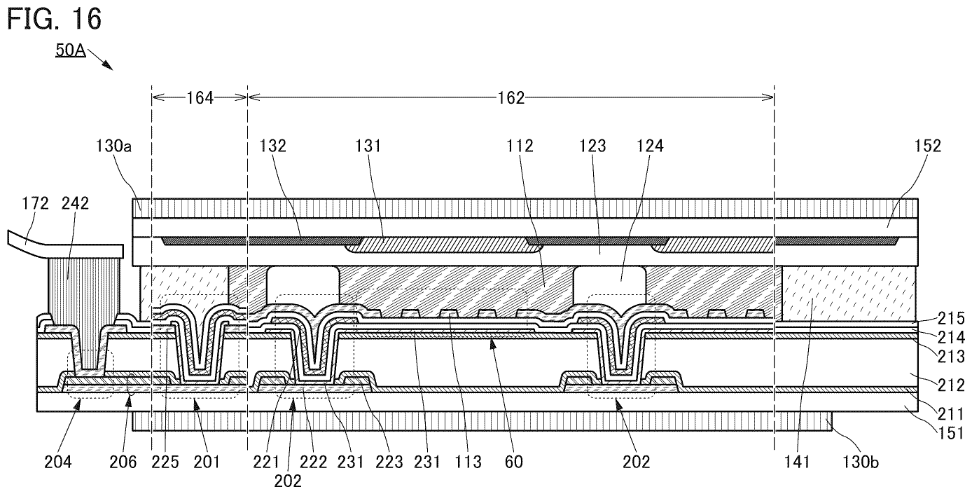

FIG. 16 illustrates an example in which the positions of the semiconductor layer 231 and the common electrode 113 are turned upside down. The common electrode 113 has a comb-like shape or includes a slit in a plan view, and is provided over the semiconductor layer 231 with the insulating layer 214 and the insulating layer 215 positioned therebetween.

In FIG. 15, the semiconductor layer 231 and the common electrode 113 are stacked with the insulating layer 216 positioned therebetween to form capacitance. Therefore, a capacitor does not need to be separately provided, and thus the aperture ratio of the pixel can be increased.

With the use of a conductive material that transmits visible light for the common electrode 113, a transmissive liquid crystal display device can be obtained. When both of the semiconductor layer 231 and the common electrode 113 are formed using a conductive material that transmits visible light, the aperture ratio can be further increased, which is preferable.

Note that for the case of a reflective liquid crystal display device, a structure in which a reflective layer that reflects visible light is provided to overlap with the liquid crystal element 60 can also be employed.

In the case where a horizontal electric field mode is employed, a liquid crystal exhibiting a blue phase for which an alignment film is not used may be used. A blue phase is one of liquid crystal phases, which is generated just before a cholesteric phase changes into an isotropic phase while the temperature of cholesteric liquid crystal is increased. Since the blue phase appears only in a narrow temperature range, a liquid crystal composition in which a chiral material is mixed to account for several weight percent or more is used for the liquid crystal layer in order to improve the temperature range. The liquid crystal composition which includes liquid crystal exhibiting a blue phase and a chiral material has a short response time and optical isotropy. In addition, the liquid crystal composition which includes liquid crystal exhibiting a blue phase and a chiral material does not need alignment treatment and has a small viewing angle dependence. An alignment film does not need to be provided and rubbing treatment is thus not necessary; accordingly, electrostatic discharge damage caused by the rubbing treatment can be prevented and defects and damage of the liquid crystal display device in the manufacturing process can be reduced.

### Cross-Sectional Structure Example 3

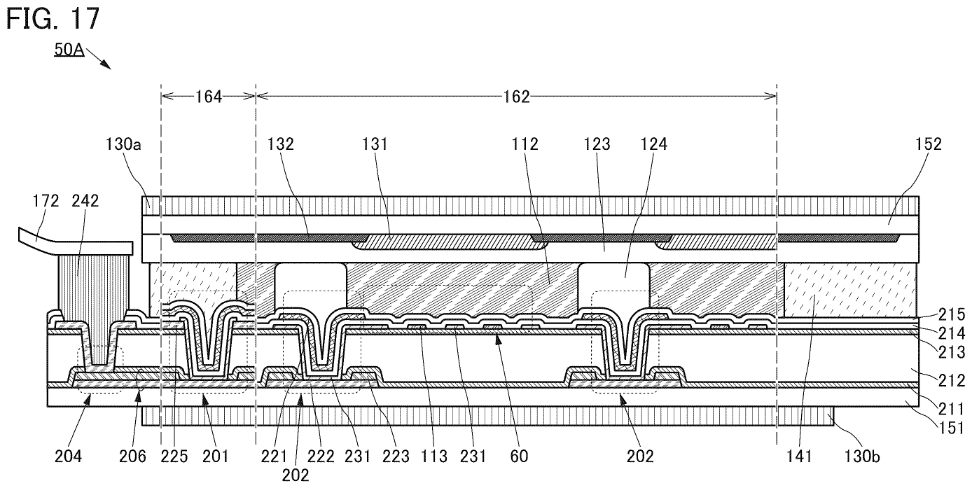

FIG. 17 illustrates an example where the liquid crystal element 60 is a liquid crystal element using an IPS mode. The liquid crystal element 60 includes a portion of the semiconductor layer 231, the liquid crystal 112, and the common electrode 113.

The portion of the semiconductor layer 231 and the common electrode 113 are provided over the insulating layer 213. In a plan view, the portion of the semiconductor layer 231 and the common electrode 113 each have a comb-like top surface shape and are provided to engage with each other. The semiconductor layer 231 and the common electrode 113 are preferably formed by processing the same conductive film. In FIG. 17, the semiconductor layer 231 and the common electrode 113 are shown with different hatching patterns for clarity.

The above is the description of the cross-sectional structure examples.

At least part of this embodiment can be implemented in combination with any of the other embodiments described in this specification, as appropriate.

### Embodiment 3

In this embodiment, a display device including a transistor of one embodiment of the present invention will be described.

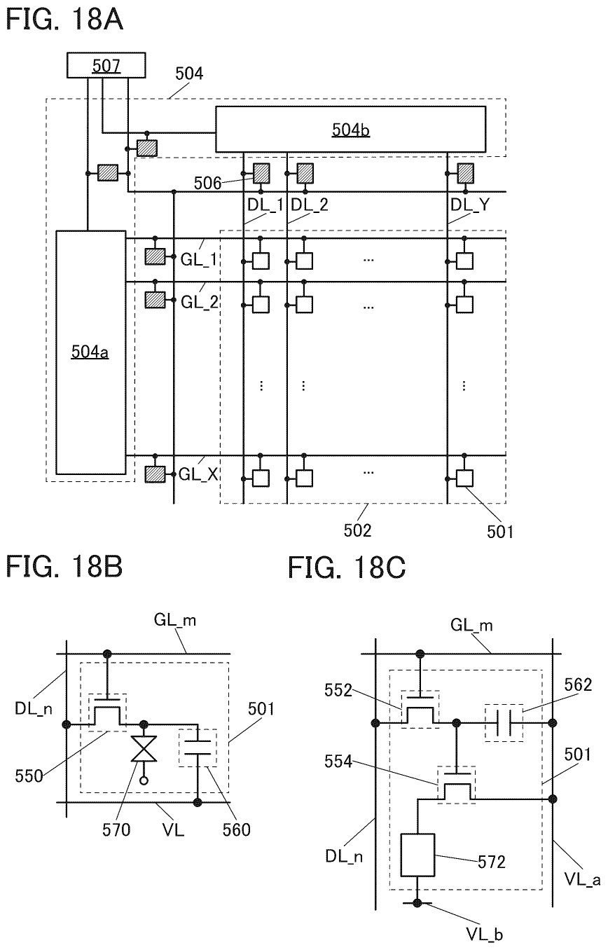

A display device in FIG. 18A includes a pixel portion 502, a driver circuit portion 504, a protective circuit 506, and a terminal portion 507. Note that the protective circuit 506 is not necessarily provided.

The transistor of one embodiment of the present invention can be used as a transistor included in one or both of the pixel portion 502 and the driver circuit portion 504. The transistor of one embodiment of the present invention may also be used in the protective circuit 506.

The pixel portion 502 includes a plurality of pixel circuits 501 arranged in X rows and Y columns (X and Y independently represent a natural number of 2 or more). Each of the pixel circuits 501 includes a circuit for driving a display element.

The driver circuit portion 504 includes driver circuits such as a gate driver 504a that outputs a scan signal to gate lines GL_1 to GL_X and a source driver 504b that supplies a data signal to data lines DL_1 to DL_Y. The gate driver 504a includes at least a shift register. The source driver 504b can be formed using a shift register, a digital-analog convertor circuit, a latch circuit, and the like.

The terminal portion 507 is a portion having terminals for inputting power, control signals, image signals, and the like to the display device from external circuits.

The protective circuit 506 is a circuit which electrically connects a wiring connected to the protective circuit 506 to another wiring when a potential out of a certain range is applied to the wiring connected to the protective circuit 506. The protective circuit 506 illustrated in FIG. 18A is connected to, for example, wirings such as a gate line GL and a data line DL. Note that the protective circuits 506 are hatched in FIG. 18A in order to distinguish the protective circuits 506 from the pixel circuits 501.

The gate driver 504a and the source driver 504b may be provided over the same substrate as the pixel portion 502, or an IC on which a gate driver circuit or a source driver circuit is formed may be mounted on a substrate provided with the pixel portion 502 by a COG (Chip On Glass) method or the like. Alternatively, an FPC (Flexible Printed Circuit) on which an IC is mounted may be attached to a substrate with an ACF (Anisotropic Conductive Film) or the like.

In particular, the pixel portion 502 and the gate driver 504a are preferably formed over the same substrate through the same manufacturing step. In that case, the transistor of one embodiment of the present invention is preferably provided in each of the pixel portion 502 and the gate driver 504a. In the case where an IC is used for the source driver 504b, a demultiplexer circuit is preferably provided over the substrate, in which case the number of IC terminals can be reduced. In that case, the transistor of one embodiment of the present invention is preferably provided in the demultiplexer circuit.

FIG. 18B illustrates a configuration example of a pixel circuit that can be used as the pixel circuit 501.

The pixel circuit 501 illustrated in FIG. 18B includes a liquid crystal element 570, a transistor 550, and a capacitor 560. The pixel circuit 501 is connected to the data line DL_n, the gate line GL_m, a potential supply line VL, and the like.

As the transistor 550, the vertical transistor of one embodiment of the present invention can be used.

The potential of one of a pair of electrodes of the liquid crystal element 570 is set in accordance with the specifications of the pixel circuit 501 as appropriate. The alignment state of the liquid crystal element 570 depends on written data. A common potential may be supplied to one of the pair of electrodes of the liquid crystal element 570 included in each of the plurality of pixel circuits 501. The potential supplied to the one of the pair of electrodes of the liquid crystal element 570 in the pixel circuit 501 may differ between rows.

The pixel circuit 501 illustrated in FIG. 18C includes a transistor 552, a transistor 554, a capacitor 562, and a light-emitting element 572. The pixel circuit 501 is connected to the data line DL_n, the gate line GL_m, a potential supply line VL_a, a potential supply line VL_b, and the like.

Note that a high power supply potential VDD is supplied to one of the potential supply line VL_a and the potential supply line VL_b, and a low power supply potential VSS is supplied to the other. The current flowing through the light-emitting element 572 is controlled in accordance with a potential supplied to a gate of the transistor 554, whereby the luminance of light emitted from the light-emitting element 572 is controlled.

Next, a pixel circuit including a memory for correcting gray levels displayed by pixels and a display device including the pixel circuit will be described below.

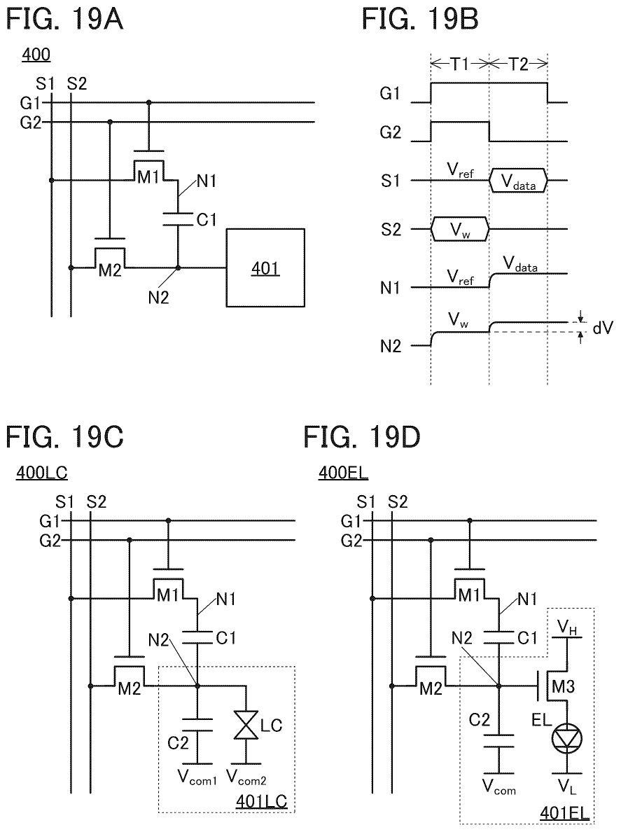

FIG. 19A is a circuit diagram of a pixel circuit 400. The pixel circuit 400 includes a transistor M1, a transistor M2, a capacitor C1, and a circuit 401. The pixel circuit 400 is connected to a wiring S1, a wiring S2, a wiring G1, and a wiring G2.

As the transistor M1 and the transistor M2, the vertical transistor of one embodiment of the present invention can be used.

A gate of the transistor M1 is connected to the wiring G1, one of a source and a drain of the transistor M1 is connected to the wiring S1, and the other of the source and the drain of the transistor M1 is connected to one electrode of the capacitor C1. A gate of the transistor M2 is connected to the wiring G2, one of a source and a drain of the transistor M2 is connected to the wiring S2, and the other of the source and the drain of the transistor M2 is connected to the other electrode of the capacitor C1 and the circuit 401.

The circuit 401 includes at least one display element. Here, a liquid crystal element is included as the display element.

A node where the transistor M1 and the capacitor C1 are connected is referred to as a node N1, and a node where the transistor M2 and the circuit 401 are connected is referred to as a node N2.

In the pixel circuit 400, when the transistor M1 is turned off, the potential of the node N1 can be retained. Furthermore, when the transistor M2 is turned off, the potential of the node N2 can be retained. A predetermined potential is written to the node N1 through the transistor M1 while the transistor M2 is off, whereby the potential of the node N2 can be changed in accordance with a change in the potential of the node N1 by capacitive coupling through the capacitor C1.

Here, the transistor using an oxide semiconductor in Embodiment 1 can be used as one or both of the transistor M1 and the transistor M2. Accordingly, the potential of the node N1 or the node N2 can be retained for a long time owing to an extremely low off-state current. Note that a transistor using a semiconductor such as silicon may be used in the case where the potential of each node is retained for a short time (specifically, in the case where the frame frequency is 30 Hz or more, for example).

### Driving Method Example

Next, an example of a method for operating the pixel circuit 400 is described with reference to FIG. 19B. FIG. 19B is a timing chart showing operation of the pixel circuit 400. Note that, for easy description, the influences of various kinds of resistance such as wiring resistance, parasitic capacitance, the threshold voltage of a transistor, and the like are not taken into consideration.

In the operation shown in FIG. 19B, one frame period is divided into a period T1 and a period T2. The period T1 is a period in which a potential is written to the node N2, and the period T2 is a period in which a potential is written to the node N1.

### Period T1

In the period T1, potentials for turning on the transistors are supplied to the wiring G1 and the wiring G2. A potential V_{ref} that is a fixed potential is supplied to the wiring S1 and a first data potential V_{w} is supplied to the wiring S2.

The potential V_{ref} is supplied from the wiring S1 to the node N1 through the transistor M1. The first data potential V_{w} is supplied from the wiring S2 to the node N2 through the transistor M2. Thus, a potential difference V_{w}−V_{ref} is held in the capacitor C1.

### Period T2

Then, in the period T2, the potential for turning on the transistor M1 is supplied to the wiring G1, and a potential for turning off the transistor M2 is supplied to the wiring G2. A second data potential V_{data} is supplied to the wiring S1. The wiring S2 may be supplied with a predetermined constant potential or brought into a floating state.

The second data potential V_{data} is supplied from the wiring S1 to the node N1 through the transistor M1. At this time, the potential of the node N2 changes only by a potential dV in accordance with the second data potential V_{data} due to capacitive coupling by the capacitor C1. That is, a potential of the sum of the first data potential V_{w} and the potential dV is input to the circuit 401. Although the potential dV is a positive value in FIG. 19B, the potential dV may be a negative value. In other words, the second data potential V_{data} may be lower than the potential V_{ref}.

Here, the potential dV is mainly determined by the capacitance value of the capacitor C1 and the capacitance value of the circuit 401. When the capacitance value of the capacitor C1 is much higher than the capacitance value of the circuit 401, the potential dV is close to the second data potential V_{data}.

As described above, the pixel circuit 400 can generate a potential supplied to the circuit 401 including the display element by combination of two kinds of data signals, so that gray levels can be corrected in the pixel circuit 400.

The pixel circuit 400 can also generate a potential exceeding the maximum potential that the source driver connected to the wiring S1 and the wiring S2 can supply. For example, in the case of using a light-emitting element, high-dynamic-range (HDR) display or the like can be performed. In the case of using a liquid crystal element, overdriving or the like can be performed.

### Application Example

### Example Using Liquid Crystal Element

A pixel circuit 400LC illustrated in FIG. 19C includes a circuit 401LC. The circuit 401LC includes a liquid crystal element LC and a capacitor C2.

One electrode of the liquid crystal element LC is connected to the node N2 and one electrode of the capacitor C2, and the other electrode of the liquid crystal element LC is connected to a wiring to which a potential V_{com2} is supplied. The other electrode of the capacitor C2 is connected to a wiring to which a potential V_{com1} is supplied.

The capacitor C2 functions as a storage capacitor. Note that the capacitor C2 is not necessarily provided.

Since a high voltage can be supplied to the liquid crystal element LC in the pixel circuit 400LC, high-speed display by overdriving, use of a liquid crystal material with a high drive voltage, or the like are possible, for example. In addition, a correction signal is supplied to the wiring S1 or the wiring S2, whereby gray levels can be corrected in accordance with an operating temperature, a deterioration level of the liquid crystal element LC, or the like.

### Example Using Light-Emitting Element

A pixel circuit 400EL illustrated in FIG. 19D includes a circuit 401EL. The circuit 401EL includes a light-emitting element EL, a transistor M3, and the capacitor C2.

A gate of the transistor M3 is connected to the node N2 and one electrode of the capacitor C2, one of a source and a drain of the transistor M3 is connected to a wiring to which a potential V_{H} is supplied, and the other of the source and the drain of the transistor M3 is connected to one electrode of the light-emitting element EL. The other electrode of the capacitor C2 is connected to a wiring to which a potential V_{com} is supplied. The other electrode of the light-emitting element EL is connected to a wiring to which a potential V_{L} is supplied.

The transistor M3 has a function of controlling current to be supplied to the light-emitting element EL. The capacitor C2 functions as a storage capacitor. The capacitor C2 is not necessarily provided.

Although the transistor M3 is connected to an anode side of the light-emitting element EL here, the transistor M3 may be connected to a cathode side. In that case, values of the potential V_{H} and the potential V_{L} can be changed as appropriate.

A large amount of current can flow in the light-emitting element EL by supplying a high potential to the gate of the transistor M3 in the pixel circuit 400EL, whereby HDR display or the like can be performed. In addition, a correction signal is supplied to the wiring S1 or the wiring S2, whereby variation in electrical characteristics of the transistor M3, the light-emitting element EL, or the like can be corrected.

Note that without limitation to the circuits illustrated in FIGS. 19C and 19D, a transistor, a capacitor, or the like may be added.

At least part of this embodiment can be implemented in combination with any of the other embodiments described in this specification as appropriate.

### Embodiment 4

In this embodiment, a structure example of a touch panel module including a touch panel and an IC will be described.

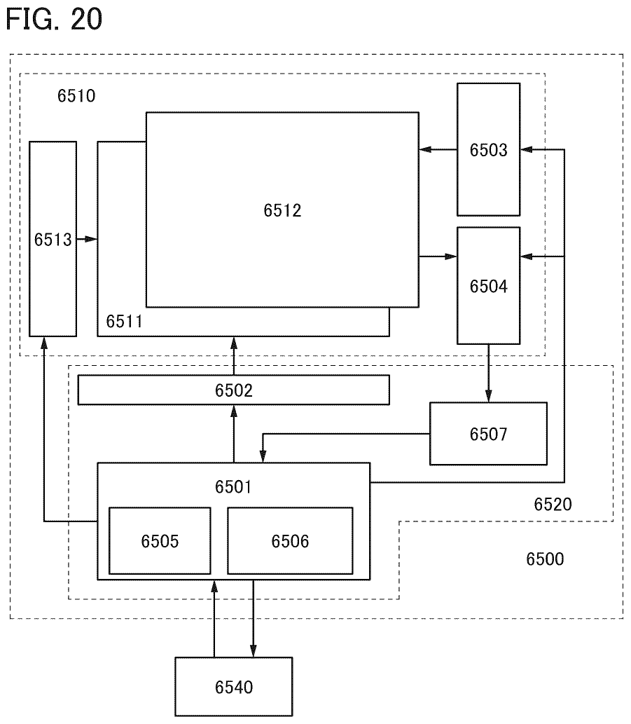

FIG. 20 is a block diagram of a touch panel module 6500. The touch panel module 6500 includes a touch panel 6510 and an IC 6520.

The touch panel 6510 includes a display portion 6511, an input portion 6512, a scan line driver circuit 6513, a sensor driver circuit 6503, and a detection circuit 6504. The display portion 6511 includes a plurality of pixels, a plurality of signal lines, and a plurality of scan lines and has a function of displaying an image. The input portion 6512 includes a plurality of sensor elements for sensing the contact or approach of an object to the touch panel 6510 to have a function of a touch sensor. The scan line driver circuit 6513 has a function of outputting a scan signal to the scan lines included in the display portion 6511.

The sensor driver circuit 6503 has a function of outputting a signal for driving a sensor element included in the input portion 6512. As the sensor driver circuit 6503, a shift register circuit and a buffer circuit can be used in combination, for example.

The detection circuit 6504 has functions of amplifying an output signal from the sensor element included in the input portion 6512 and outputting it to an AD convertor circuit 6507.

The display portion 6511 and the input portion 6512 are separately illustrated in the touch panel 6510 for simplicity; however, a so-called in-cell touch panel having both a function of displaying an image and a function of a touch sensor may be employed.

As a touch sensor that can be used for the input portion 6512, a capacitive touch sensor can be used. Examples of the capacitive touch sensor are a surface capacitive touch sensor and a projected capacitive touch sensor. Examples of the projected capacitive touch sensor include a self-capacitive touch sensor and a mutual capacitive touch sensor. The use of a mutual capacitive touch sensor is preferable because multiple points can be sensed simultaneously.

Note that one embodiment of the present invention is not limited thereto, and any of various sensors that can sense the approach, contact, or press of an object such as a finger or a stylus can be used as the input portion 6512. For the touch sensor, in addition to a capacitive type, a variety of types such as a resistive type, a surface acoustic wave type, an infrared type, and an optical type can be used, for example.

As typical examples of the in-cell touch panel, a hybrid in-cell type and a full-in-cell type can be given. The hybrid in-cell type refers to a structure in which an electrode or the like included in a touch sensor is provided over a substrate that supports a display element and a counter substrate or over the counter substrate. Meanwhile, a full-in-cell type refers to a structure in which an electrode or the like included in a touch sensor is provided over a substrate that supports a display element. In the case of a full-in-cell touch panel, a structure of a counter substrate can be simplified, which is preferable. In particular, when an electrode included in a display element also serves as an electrode in a touch sensor in a full-in-cell touch sensor, a manufacturing process can be simplified and manufacturing cost can be reduced, which is preferable.

The resolution of the display portion 6511 is preferably as high as HD (number of pixels: 1280×720), FHD (number of pixels: 1920×1080), WQHD (number of pixels: 2560×1440), WQXGA (number of pixels: 2560×1600), 4K (number of pixels: 3840×2160), or 8K (number of pixels: 7680×4320). In particular, resolution of 4K, 8K, or higher is preferable. The pixel density (definition) of the pixels in the display portion 6511 is higher than or equal to 300 ppi, preferably higher than or equal to 500 ppi, more preferably higher than or equal to 800 ppi, more preferably higher than or equal to 1000 ppi, more preferably higher than or equal to 1200 ppi. The display portion 6511 with such high resolution and high definition enables an increase in a realistic sensation, sense of depth, and the like.

The IC 6520 includes a circuit unit 6501, a signal line driver circuit 6502, and the AD convertor circuit 6507. The circuit unit 6501 includes a timing controller 6505, an image processing circuit 6506, or the like.

The signal line driver circuit 6502 has a function of outputting an image signal (also referred to as a video signal) that is an analog signal to the signal lines included in the display portion 6511. For example, the signal line driver circuit 6502 can have a structure in which a shift register, a digital-analog convertor circuit (DAC), a latch circuit, a buffer circuit, and the like are combined. The touch panel 6510 may include a demultiplexer circuit connected to the signal lines.

The AD convertor circuit 6507 has a function of converting an analog signal input from the detection circuit 6504 to a digital signal and outputting the digital signal to the circuit unit 6501. The AD convertor circuit 6507 can include an amplifier circuit in addition to an analog-digital convertor circuit (ADC), for example.

The image processing circuit 6506 included in the circuit unit 6501 has a function of generating and outputting a signal for driving the display portion 6511 of the touch panel 6510, a function of generating and outputting a signal for driving the input portion 6512, and a function of analyzing a signal output from the input portion 6512 and outputting the signal to a CPU 6540.

More specifically, the image processing circuit 6506 has a function of generating a video signal in accordance with an instruction from the CPU 6540, for example. Furthermore, the image processing circuit 6506 has a function of performing signal processing on a video signal in accordance with the specifications of the display portion 6511, converting the signal into an analog video signal, and supplying the analog video signal to the signal line driver circuit 6502. The image processing circuit 6506 has a function of generating a driver signal to be output to the sensor driver circuit 6503 in accordance with an instruction from the CPU 6540. The image processing circuit 6506 has a function of analyzing a signal input from the detection circuit 6504 through the AD convertor circuit 6507 and outputting the signal to the CPU 6540 as positional information.

The timing controller 6505 may have a function of generating and outputting a signal (e.g., a clock signal or a start pulse signal) output to the scan line driver circuit 6513 and the sensor driver circuit 6503 on the basis of a synchronization signal included in a video signal or the like on which the image processing circuit 6506 performs processing. Furthermore, the timing controller 6505 may have a function of generating and outputting a signal for determining timing when the sensing circuit 6504 outputs a signal. Here, the timing controller 6505 preferably outputs synchronized signals as the signal output to the scan line driver circuit 6513 and the signal output to the sensor driver circuit 6503. In particular, it is preferable that a period in which data in a pixel in the display portion 6511 is rewritten and a period in which sensing is performed with the input portion 6512 be separately provided. For example, the touch panel 6510 can be driven by dividing one frame period into a period in which data in a pixel is rewritten and a period in which sensing is performed. Furthermore, detection sensitivity and detection accuracy can be increased, for example, by providing two or more sensing periods in one frame period.

The image processing circuit 6506 can include a processor, for example. A microprocessor such as a DSP (Digital Signal Processor) or a GPU (Graphics Processing Unit) can be used, for example. Furthermore, such a microprocessor may be obtained with a PLD (Programmable Logic Device) such as an FPGA (Field Programmable Gate Array) or an FPAA (Field Programmable Analog Array). The image processing circuit 6506 interprets and executes instructions from various programs with the processor to process various kinds of data and control programs. The programs executed by the processor may be stored in a memory region included in the processor or a memory device which is additionally provided.

Note that for one or more of the display portion 6511, the input portion 6512, the scan line driver circuit 6513, the sensor driver circuit 6503, and the detection circuit 6504 included in the touch panel 6510, it is preferable to use a transistor which has an extremely low off-state current and in which an oxide semiconductor is used for a channel formation region. With the use of the transistor having an extremely low off-state current as a switch for retaining electric charge (data) which flows into a capacitor serving as a memory element, a long data retention period can be ensured. The transistor may be used for the circuit unit 6501, the signal line driver circuit 6502, and the AD convertor circuit 6507 included in the IC 6520 and the CPU 6540 or the like provided outside. For example, by utilizing the characteristic for a register, a cache memory, or the like of the image processing circuit 6506, what is called normally off computing is achieved where the image processing circuit 6506 operates only when needed, data on the immediately preceding processing is stored in the memory element in the rest of the time, and power supply to the image processing circuit 6506 is stopped when the image processing circuit 6506 is not used; thus, power consumption of the touch panel module 6500 and an electronic device on which the touch panel module 6500 is mounted can be reduced.

Although the structure where the circuit unit 6501 includes the timing controller 6505 and the image processing circuit 6506 is employed here, the image processing circuit 6506 itself or a circuit having a function of part of the image processing circuit 6506 may be provided outside the IC 6520. Alternatively, the CPU 6540 may have a function of the image processing circuit 6506 or part thereof. For example, the circuit unit 6501 can include the signal line driver circuit 6502, the timing controller 6505, and the AD convertor circuit 6507.

Although the example where the IC 6520 includes the circuit unit 6501 is shown here, the structure where the circuit unit 6501 is not included in the IC 6520 may be employed. In that case, the IC 6520 can include the signal line driver circuit 6502 and the AD convertor circuit 6507. For example, in the case where the touch panel module 6500 includes a plurality of ICs, an IC including the circuit unit 6501 may be separately provided and a plurality of ICs 6520 without the circuit unit 6501 may be provided, and alternatively, the IC 6520 and an IC including only the signal line driver circuit 6502 can be provided in combination.

When an IC has a function of driving the display portion 6511 of the touch panel 6510 and a function of driving the input portion 6512 as described above, the number of ICs mounted on the touch panel module 6500 can be reduced; accordingly, cost can be reduced.

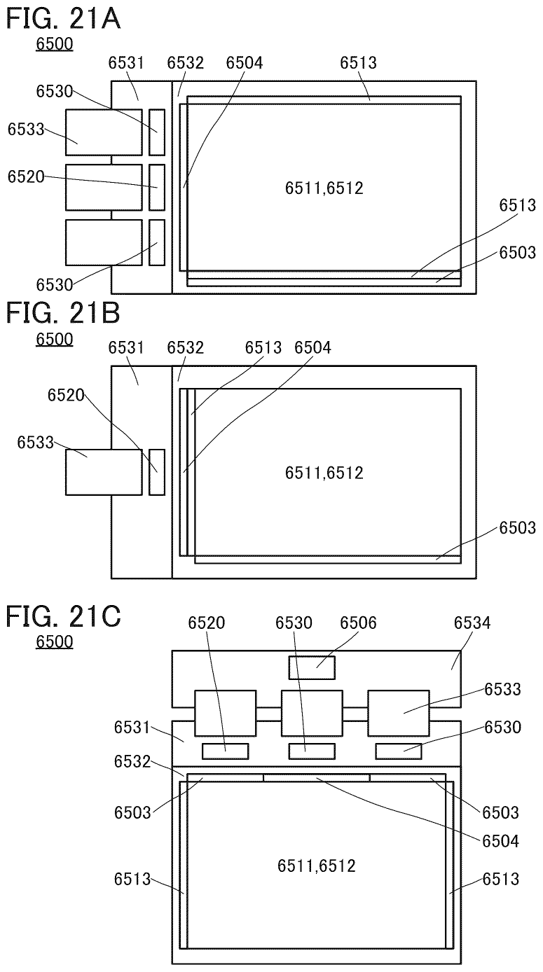

FIG. 21A, FIG. 21B, and FIG. 21C each are a schematic diagram of the touch panel module 6500 on which the IC 6520 is mounted.

In FIG. 21A, the touch panel module 6500 includes a substrate 6531, a counter substrate 6532, a plurality of FPCs 6533, the IC 6520, ICs 6530, and the like. The display portion 6511, the input portion 6512, the scan line driver circuits 6513, the sensor driver circuit 6503, and the detection circuit 6504 are provided between the substrate 6531 and the counter substrate 6532. The IC 6520 and the ICs 6530 are mounted on the substrate 6531 by a COG (Chip On Glass) method.

The IC 6530 is an IC in which only the signal line driver circuit 6502 is provided in the above-described IC 6520 or an IC in which the signal line driver circuit 6502 and the circuit unit 6501 are provided in the above-described IC 6520. The IC 6520 and the IC 6530 are supplied with a signal from the outside through the FPCs 6533. Furthermore, a signal can be output to the outside from the IC 6520 or the IC 6530 through the FPC 6533.

FIG. 21A illustrates an example of a structure where two scan line driver circuits 6513 are provided such that the display portion 6511 is sandwiched therebetween. In the structure, the ICs 6530 are provided in addition to the IC 6520. Such a structure can be suitably used in the case where the display portion 6511 has extremely high resolution.

FIG. 21B illustrates an example where one IC 6520 and one FPC 6533 are provided. It is preferable to bring functions into one IC 6520 in this manner because the number of components can be reduced. In the example in FIG. 21B, the scan line driver circuit 6513 is provided along a side close to the FPC 6533 among two short sides of the display portion 6511.

FIG. 21C illustrates an example where a PCB (Printed Circuit Board) 6534 on which the image processing circuit 6506 and the like are mounted is provided. The IC 6520 and the ICs 6530 over the substrate 6531 are electrically connected to the PCB 6534 through the FPCs 6533. Here, the above-described structure without the image processing circuit 6506 can be applied to the IC 6520.

In FIG. 21A, FIG. 21B, and FIG. 21C, the IC 6520 and the IC 6530 may be mounted on the FPC 6533, not on the substrate 6531. For example, the IC 6520 and the IC 6530 may be mounted on the FPC 6533 by a COF method, a TAB method, or the like.

A structure where the FPC 6533, the IC 6520 (and the IC 6530), or the like is provided on a short side of the display portion 6511 as illustrated in FIG. 21A and FIG. 21B enables a narrow bezel; thus, the structure is preferably used for electronic devices such as smartphones, mobile phones, and tablet terminals, for example. The structure with the PCB 6534 illustrated in FIG. 21C can be suitably used for television devices, monitor devices, tablet terminals, or laptop personal computers, for example.

At least part of this embodiment can be implemented in combination with any of the other embodiments described in this specification, as appropriate.

### Embodiment 5

In this embodiment, an electronic device of one embodiment of the present invention will be described.

Electronic devices of this embodiment are each provided with the display device of one embodiment of the present invention in a display portion. The display device of one embodiment of the present invention can be easily increased in resolution and definition. Thus, the display device of one embodiment of the present invention can be used for a display portion of a variety of electronic devices.

A semiconductor device of one embodiment of the present invention can also be applied to any other portion of an electronic device than a display portion. For example, the semiconductor device of one embodiment of the present invention is preferably used for a control portion or the like of an electronic device because lower power consumption can be achieved.

Examples of the electronic devices include a digital camera, a digital video camera, a digital photo frame, a mobile phone, a portable game console, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display device of one embodiment of the present invention can have a high definition, and thus can be used for an electronic device having a relatively small display portion. Examples of such an electronic device include watch-type and bracelet-type information terminal devices (wearable devices) and wearable devices worn on the head, such as a VR device like a head-mounted display, a glasses-type AR device, and an MR device.

The electronic device in this embodiment may include a sensor (a sensor having a function of sensing, detecting, or measuring force, displacement, position, speed, acceleration, angular velocity, rotational frequency, distance, light, liquid, magnetism, temperature, a chemical substance, sound, time, hardness, electric field, current, voltage, electric power, radiation, flow rate, humidity, gradient, oscillation, a smell, or infrared rays).

The electronic device in this embodiment can have a variety of functions. For example, the electronic device in this embodiment can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

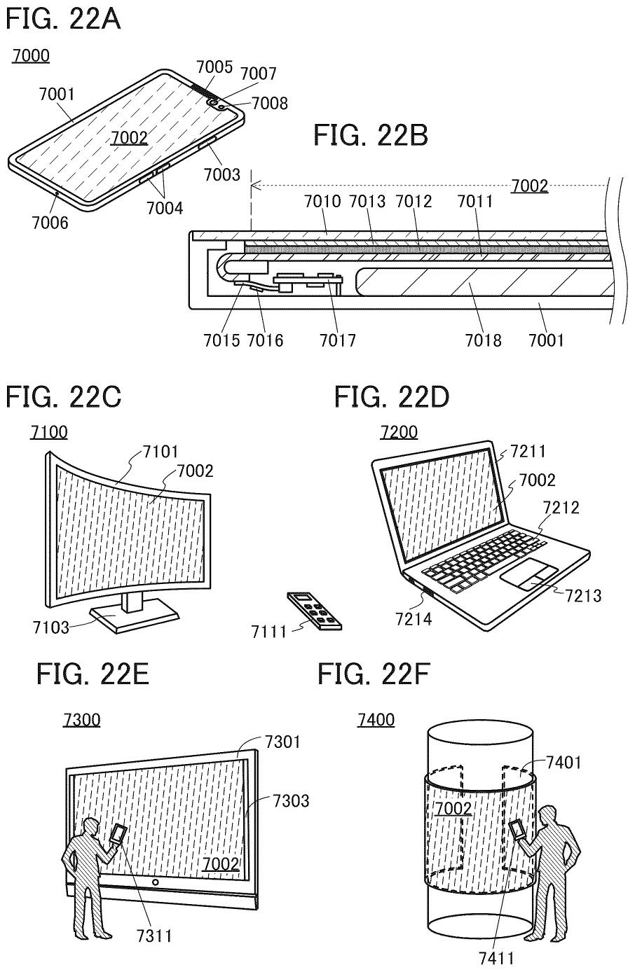

An electronic device 7000 illustrated in FIG. 22A is a portable information terminal that can be used as a smartphone.

The electronic device 7000 includes a housing 7001, a display portion 7002, a power supply button 7003, buttons 7004, a speaker 7005, a microphone 7006, a camera 7007, a light source 7008, and the like. The display portion 7002 has a touch panel function.

The display device of one embodiment of the present invention can be used in the display portion 7002.

FIG. 22B is a schematic cross-sectional view including an end portion of the housing 7001 on the microphone 7006 side.

A protection member 7010 having a light-transmitting property is provided on the display surface side of the housing 7001. A display panel 7011, an optical member 7012, a touch sensor panel 7013, a printed circuit board 7017, a battery 7018, and the like are provided in a space surrounded by the housing 7001 and the protection member 7010.

The display panel 7011, the optical member 7012, and the touch sensor panel 7013 are fixed to the protection member 7010 with an adhesive layer (not illustrated).

Part of the display panel 7011 is folded back in a region outside the display portion 7002, and an FPC 7015 is connected to the part that is folded back. An IC 7016 is mounted on the FPC 7015. The FPC 7015 is connected to a terminal provided on the printed circuit board 7017.

A display device of one embodiment of the present invention can be used as the display panel 7011. Thus, an extremely lightweight electronic device can be achieved. Since the display panel 7011 is extremely thin, the battery 7018 with high capacity can be mounted without an increase in the thickness of the electronic device. Moreover, part of the display panel 7011 is folded back so that a connection portion with the FPC 7015 is provided on the back side of the pixel portion, whereby an electronic device with a narrow bezel can be achieved.

FIG. 22C illustrates an example of a television device. In a television device 7100, a display portion 7002 is incorporated in a housing 7101. Here, the housing 7101 is supported by a stand 7103.

The display device of one embodiment of the present invention can be used in the display portion 7002.

Operation of the television device 7100 illustrated in FIG. 22C can be performed with an operation switch provided in the housing 7101 and a separate remote controller 7111. Alternatively, the display portion 7002 may include a touch sensor, and the television device 7100 may be operated by touch on the display portion 7002 with a finger or the like. The remote controller 7111 may be provided with a display portion for displaying information output from the remote controller 7111. With operation keys or a touch panel provided in the remote controller 7111, channels and volume can be controlled and videos displayed on the display portion 7002 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) data communication can be performed.

FIG. 22D illustrates an example of a laptop personal computer. The laptop personal computer 7200 includes a housing 7211, a keyboard 7212, a pointing device 7213, an external connection port 7214, and the like. The display portion 7002 is incorporated in the housing 7211.

The display device of one embodiment of the present invention can be used in the display portion 7002.

FIG. 22E and FIG. 22F illustrate examples of digital signage.

Digital signage 7300 illustrated in FIG. 22E includes a housing 7301, the display portion 7002, a speaker 7303, and the like. The digital signage 7300 can also include an LED lamp, an operation key (including a power switch or an operation switch), a connection terminal, a variety of sensors, a microphone, and the like.

FIG. 22F illustrates digital signage 7400 attached to a cylindrical pillar 7401. The digital signage 7400 includes the display portion 7002 provided along a curved surface of the pillar 7401.

The display device of one embodiment of the present invention can be used in the display portion 7002 illustrated in each of FIG. 22E and FIG. 22F.

A larger area of the display portion 7002 can increase the amount of information that can be provided at a time. The larger display portion 7002 attracts more attention, so that the effectiveness of the advertisement can be increased, for example.

The use of a touch panel in the display portion 7002 is preferable because in addition to display of a still image or a moving image on the display portion 7002, intuitive operation by a user is possible. Moreover, for an application for providing information such as route information or traffic information, usability can be enhanced by intuitive operation.

As illustrated in FIG. 22E and FIG. 22F, it is preferable that the digital signage 7300 or the digital signage 7400 can work with an information terminal 7311 or an information terminal 7411, such as a smartphone that a user has, through wireless communication. For example, information of an advertisement displayed on the display portion 7002 can be displayed on a screen of the information terminal 7311 or the information terminal 7411. By operation of the information terminal 7311 or the information terminal 7411, display on the display portion 7002 can be switched.

It is possible to make the digital signage 7300 or the digital signage 7400 execute a game with use of the screen of the information terminal 7311 or the information terminal 7411 as an operation means (controller). Thus, an unspecified number of users can join in and enjoy the game concurrently.

At least part of this embodiment can be implemented in combination with any of the other embodiments described in this specification, as appropriate.

### REFERENCE NUMERALS

10a: transistor, 10: transistor, 11: substrate, 12: substrate, 20: opening, 21: semiconductor layer, 22: insulating layer, 23: conductive layer, 24: conductive layer, 25: insulating layer, 26: conductive layer, 28: insulating layer, 29a: insulating layer, 29b: insulating layer, 30: liquid crystal element, 31: conductive layer, 32: conductive layer, 33: liquid crystal, 34: insulating layer, 35: conductive layer, 41: alignment film, 42: alignment film, 43: coloring layer, 44: light-blocking layer, 45: insulating layer, 46: insulating layer

1. A display device comprising:
a transistor;
a liquid crystal element; and
a first insulating layer comprising a first side surface,
wherein the transistor comprises:
a semiconductor layer comprising a metal oxide;
a gate insulating layer;
a gate electrode; and
a first conductive layer,
wherein the first side surface is positioned over the first conductive layer,
wherein the semiconductor layer is in contact with a top surface of the first conductive layer and the first side surface, and comprises a portion positioned over the first insulating layer,
wherein the gate insulating layer comprises a surface facing the first side surface with the semiconductor layer therebetween,
wherein the gate electrode comprises a surface facing the first side surface with the semiconductor layer and the gate insulating layer therebetween,
wherein the liquid crystal element comprises:
a liquid crystal;
a second conductive layer; and
the semiconductor layer,
wherein the second conductive layer is positioned over the first insulating layer, and comprises a portion overlapping with the semiconductor layer.

2. A display device comprising:
a transistor;
a liquid crystal element; and
a first insulating layer,
wherein the transistor comprises:
a semiconductor layer comprising a metal oxide;
a gate insulating layer;
a gate electrode; and
a first conductive layer,
wherein the first insulating layer comprises an opening reaching the first conductive layer and a first side surface positioned in the opening,
wherein the semiconductor layer is in contact with a top surface of the first conductive layer and the first side surface, and comprises a portion positioned over the first insulating layer,
wherein the gate insulating layer comprises a surface facing the first side surface with the semiconductor layer therebetween,
wherein the gate electrode comprises a surface facing the first side surface with the semiconductor layer and the gate insulating layer therebetween,
wherein the liquid crystal element comprises:
a liquid crystal;
a second conductive layer; and
the semiconductor layer,
wherein the second conductive layer is positioned over the first insulating layer, and comprises a portion overlapping with the semiconductor layer.

3. The display device according to claim 1,
wherein the first insulating layer comprises a first insulating film and a second insulating film over the first insulating film,
wherein the second insulating film comprises more hydrogen than the first insulating film, and
wherein the semiconductor layer is provided in contact with the second insulating film.

4. The display device according to claim 3,
wherein the first insulating film comprises an oxide, and
wherein the second insulating film comprises a nitride.

5. The display device according to claim 1,
wherein the second conductive layer is positioned over the semiconductor layer and comprises a metal oxide, and
wherein the gate insulating layer comprises a portion positioned between the second conductive layer and the semiconductor layer.

6. The display device according to claim 5, wherein the second conductive layer is provided over the gate insulating layer.

7. The display device according to claim 5, further comprising a second insulating layer over the gate insulating layer,
wherein the second conductive layer comprises a portion overlapping with the semiconductor layer with the gate insulating layer and the second insulating layer therebetween.

8. The display device according to claim 7, wherein the second conductive layer comprises a portion overlapping with the gate electrode with the second insulating layer therebetween.

9. The display device according to claim 1, further comprising a second insulating layer over the second conductive layer,
wherein the semiconductor layer comprises a portion overlapping with the second conductive layer with the second insulating layer therebetween.

10. The display device according to claim 9,
wherein the first insulating layer comprises a first insulating film and a second insulating film over the first insulating film,
wherein the second conductive layer is positioned over the second insulating film,
wherein the second insulating layer comprises more hydrogen than the first insulating film, and
wherein the semiconductor layer is provided in contact with the second insulating layer.

11. A display device comprising:
a transistor;
a liquid crystal element; and
a first insulating layer,
wherein the transistor comprises:
a semiconductor layer comprising a metal oxide;
a gate insulating layer;
a gate electrode; and
a first conductive layer,
wherein the semiconductor layer is in contact with a top surface of the first conductive layer and a first side surface of the first insulating layer,
wherein the semiconductor layer comprises a portion positioned over the first insulating layer,
wherein the liquid crystal element comprises:
a liquid crystal;
a second conductive layer; and
the semiconductor layer,
wherein the second conductive layer is positioned over the first insulating layer, and
wherein the second conductive layer comprises a portion overlapping with the semiconductor layer.
